(19) United States
(12) Patent Application Publication
(10) Pub. No.: US 2026/0332487 A1
(43) Pub. Date: Oct. 22, 2026

(54) METHODS AND APPARATUSES FOR PERFOMING DIGITAL PREDISTORTION USING A COMBINATION MODEL

(71) Applicant: Telefonaktiebolaget LM Ericsson (PUBL), Stockholm (SE)

(72) Inventors: Sener DIKMESE, Sundbyberg (SE); Ang FENG, Solna (SE); Hao GAO, Beijing (CN); Pablo PASCUAL, Sundbyberg (SE); Mats GAN KLINGBERG, Enebyberg (SE)

(21) Appl. No.: 19/115,889

(22) PCT Filed: Dec. 27, 2022
(86) PCT No.: PCT/CN2022/142330

§ 371 Date: Mar. 27, 2025

(30) Foreign Application Priority Data
Sep. 30, 2022 (WO) PCT/CN2022/123379

(51) Int. Cl. H04L 41/16; H03F 1/32

(52) U.S. Cl. CPC H04L 41/16; H03F 1/3247

(57) ABSTRACT

Embodiments described herein relate to methods and apparatuses for performing digital predistortion, DPD, to provide a transmit signal, z(n) wherein the transmit signal, z(n), is for deriving one or more amplifier signals, zₘ(n), for driving one or more power amplifiers, wherein the one or more power amplifiers are associated with a respective one or more antenna elements. A method comprises: receiving a first signal, x(n); inputting the first signal, x(n), into a combination model, wherein the combination model comprises a machine learning, ML, model and a memory polynomial, MP, model; and outputting the transmit signal z(n), from the combination model.

### TECHNICAL FIELD

Embodiments described herein relate to methods and apparatuses for performing digital predistortion using a combination model, and methods and apparatuses for training such a combination model.

### BACKGROUND

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

Massive multiple input multiple output (M-MIMO) oriented systems are considered to be one of the key enablers in terms of enhanced spectral and energy efficiency in today's wireless communication networks (e.g. fourth generation (4G) long term evolution (LTE)/fifth generation (5G) and 5G beyond systems).

Three structures of beamforming, namely “analog”, “digital” and “hybrid analog-digital (HAD)” beamforming, are considered (see references [1] to [4]). Fully digital beamforming at the transmitter, which requires a dedicated transmitter chain for each antenna, may comprise huge hardware and computational complexity. In contrast, analog beamforming at the transmitter, implemented by a set of phase shifters, requires less hardware cost and power consumption. However, the capacity of analog beamforming is constrained by the low degree of freedom.

Due to the aforementioned limitations associated with solely analog or solely digital beamforming, a HAD beamforming transmitter may be considered to provide a better balance between cost and capacity given that the overall transmitter comprises antenna subsystems of some number of antennas, which are connected to a single radio frequency (RF) transmitter chain via a time-domain beamforming unit.

In wireless communication devices, such as base stations and user equipments (UEs), nonconstant-envelope I/Q modulated signals such as orthogonal frequency division multiplexing (OFDM) and filtered OFDM are used for 4G LTE and 5G, respectively. These signals (for example, together with M-MIMO systems) naturally excite the nonlinearities of the transmitter, especially of the power amplifier (PA). Additionally, the power efficiency of the PAs, which are the most power-hungry components in the devices, may be required to be as high as possible.

Different compensation approaches for the linearization of PAs are considered in the state-of-the-art literatures (see references [1] to [5]). Digital predistortion (DPD), which is commonly used in both academia and industry, is becoming more and more popular in both the single antenna/small number of antennas systems and in large-scale antennas/M-MIMO systems.

Behavioral modeling of PA and DPD may be a key role in modern wireless transmitter design. To improve the performance in the design of PA or DPD, behavioral modeling techniques such as predicting the nonlinearity of PA or DPD are very critical and of particular interest. For the sake of compactness, we denote PA and DPD as nonlinear devices, where PA is an analog nonlinear device implemented by amplifier transistors, and DPD is a digital nonlinear device implemented by switched-mode transistors.

Next generation systems considering two or more carrier combinations, together with wideband and multiband scenarios, have new challenges for the modelling of the nonlinear devices and components, especially for PA and DPD. This is particularly true for 5G and beyond products. In the rest of exposition, without loss of generality, the invention steps are described by DPD modelling. But it is straightforward to be applied to PA modelling.

Polynomial based models, such as a memory polynomial (MP) and generalized MP (GMP), have been widely used for DPD modelling in both industry and academia (see references [4] and [6]). Herein, the term MP model will be used to encompass both MP and GMP models.

While MP models naturally give significant modeling performance in single antenna/small number of antenna systems, an MP model requires huge computational complexity, due to the necessity of having DPD in each transmitter chain, in digital beamforming of large-scale antenna/M-MIMO systems.

While MP reaches the significant modeling performance due to its robust mathematical model, there are at least two problems that may hinder its development. Firstly, it is needed to find out the optimal address and data delays for obtaining a good performance to meet the requirement of Federal Commission Committee (FCC) and 3rd Generation Partnership Project (3GPP). This procedure needs huge computational complexity and prolongs time-to-market. Secondly, the polynomial based model is only valid within a narrow power range. Basically, to enhance the performance, MP needs to be overfitted into a specific scenario, which actually degrades its performance if it is combined with dynamic traffic, dynamic operation (such as envelope tracking, beam switching), or dynamic environment (such as temperature, hardware aging). Hence, this need to be overfitted is a limiting factor in the applicability of MP based modelling.

With the growing attention on wireless communications, the evolution of emerging RF systems has brought distinct features with new challenges for the compensation of PA nonlinearities. Complex PA architectures, such as multiband and multimode PAs, which significantly improve the energy efficiency of the system, are difficult to be compensated in terms of the nonlinearity with the desired linear gain. Additionally, it is very important to model DPD accurately over wider frequency ranges, resulting from the increased signal bandwidths appearing with the new waveforms, such as new radio (NR) in 5G.

On the other hand, with the new waveforms such as NR in 5G and 5G beyond including the wider signal bandwidth, it is becoming more critical to compensate the nonlinearity and the memory effects accurately over wider frequency range (see references [4] to [8]).

In addition to the above challenges in a single antenna system and/or traditional small number of antenna systems, the spectral efficiency and the energy efficiency, both of which are fundamental objectives of M-MIMO, are compromised (see references [5] and [11]). The out-of-band emission due to PA nonlinearity is investigated in both the single antenna and M-MIMO transmitter scenarios (see references [5] and [8]). According to the results, due to the M-MIMO structure, adjacent channel emission power ratio (ACEPR), also referred to as adjacent channel leakage ratio (ACLR), caused by PA nonlinearity is, on average, equal to the single antenna scenario when transmitting with the same total sum-power. This emphasizes that when a highly nonlinear PA is used per RF chain, tremendous out-of-band emission/distortion is caused in M-MIMO structures that creates more interference on neighboring channel transmissions with respect to the single antenna configuration and/or violates the spurious emission limits.

In terms of the quality of the signal under PA nonlinearity, significant error vector magnitude (EVM) degradation is shown in reference in a M-MIMO base station. Additionally, at least 6 dB backoff is required to reach the maximum targeted data rate (see reference [12]).

Additionally, when practical models are considered as in reference [13], there is significant degradation on the signal to interference plus noise ratio (SINR).

When the PA nonlinearity is present due to practical PA, the most harmful distortions are in the same direction as the main beam in the case of a single user per array and line-of-sight (LOS). In an example scenario in which a victim user lies in the same direction as an intended user, this creates significant interference to the victim user.

The use of backoff instead of enhanced DPD solutions may be an alternative solution to compensate the non-linear distortion of PAs, but this is not an attractive approach due to the requirement of using larger PAs operating in the linear region. The use of backoff also creates a problem with both the cost and size of each RF chain, which would increase, and the energy efficiency, which would decrease.

In addition to above mentioned challenges, in today's M-MIMO structures such as 4G LTE-A and 5G, the transmission power varies with real-time traffic. This may also be referred to as “dynamic traffic effects”. These effects mean that the dynamic changes appearing on the PA inputs can have significant impact on the nonlinear behavior of each PA. This may result in an exponential impact when the M-MIMO transmitter is considered.

In addition, the memory effects are becoming significantly important under wideband and multiband scenarios. To handle the memory effects in a good way, optimal address and data delays of the filters called “tap optimization” should be considered into MP model to obtain the good modeling and compensation performance. Typically, it is impossible to consider all delays in the predefined range, which finds out very large dimension in the DPD modeling. To overcome the high dimension problem, a few discrete delays are usually applied in practice, but applying incorrect address and data delays in the filters significantly decreases the performance. Additionally, the correct delays are hidden in the signal and cannot be found in a straightforward manner. A critical task in optimization is still to find out the optimal address and data delays in the filters according to the memory effects. Searching the optimal delays normally requires a tremendous amount of time and hence, both design cost and time-to-market are increased.

Recently, different techniques have been proposed to find the optimal address and data delays with relatively quicker searching instead of exhaustive researching. The study in uses the greedy pursuit framework into LUT model. In a block orthogonal matching pursuit (B-OMP) is used to extend the method of into more general cases.

However, the complexity of above-mentioned approaches is still quite high, and only feasible for offline searching. For instance, not all carrier configurations can be evaluated on the offline testbed. For this reason, carrier configurations may need to be divided into several clusters. All configurations in one cluster share the same delays. Specifically, only one typical case will be optimized based on the experimental results, and other cases in the same cluster have to be approximated by the experimented case. As it is well known that the PA characteristics usually show different memory effects with respect to the configured carriers. It is highly possible to have the significant performance degradation due to this approximation. Moreover, how to do clustering is not straightforward, and this also requires huge amounts of time to obtain reasonably good results. Due to this, it may be considered vital to propose new approaches which are not sensitive to the optimal address and data delays in the filters for both PA and DPD modeling.

### SUMMARY

According to some embodiments there is provided a method of performing digital predistortion, DPD, to provide a transmit signal, z(n) wherein the transmit signal, z(n), is for deriving one or more amplifier signals, zₘ(n), for driving one or more power amplifiers, wherein the one or more power amplifiers are associated with a respective one or more antenna elements. The method comprises receiving a first signal, x(n); inputting the first signal, x(n), into a combination model, wherein the combination model comprises a machine learning, ML, model and a memory polynomial, MP, model; and outputting the transmit signal z(n), from the combination model.

According to some embodiments there is provided a method of training a combination model for performing digital predistortion to provide a transmit signal, z(n) wherein the transmit signal, z(n), is for deriving one or more amplifier signals, zₘ(n), for driving one or more power amplifiers, wherein the one or more power amplifiers are associated with a respective one or more antenna elements, wherein the combination model comprises a ML model and a MP model. The method comprises training ML model during a first time period; disabling training of the MP model during the first time period; training the MP model during a second time period; and disabling training of the ML model during the second time period.

According to some embodiments there is provided a DPD module for performing digital predistortion, DPD, to provide a transmit signal, z(n) wherein the transmit signal, z(n), is for deriving one or more amplifier signals, zₘ(n), for driving one or more power amplifiers wherein the one or more power amplifiers are associated with a respective one or more antenna elements, wherein the combination model comprises a ML model and a MP model. The DPD module comprises processing circuitry configured to: receive a first signal, x(n); and input the first signal x(n) into a combination model, wherein the combination model comprises a machine learning, ML, model and a memory polynomial, MP, model; and output the transmit signal z(n) from the combination model.

According to some embodiments there is provided a DPD module for training a combination module to perform digital predistortion, DPD, wherein the combination module comprises a ML model and a MP model. The DPD module comprises processing circuitry configured to: train the ML model during a first time period; disable training of the MP model during the first time period; train the MP model during a second time period; and disable training of the ML model during the second time period.

Aspects and examples of the present disclosure thus provide methods and apparatuses for performing DPD, in particular, for performing DPD in the context of HAD MIMO beamforming.

For the purposes of the present disclosure, the term “ML model” encompasses within its scope the following concepts:
Machine Learning (ML) algorithms, comprising processes or instructions through which data may be modified by a model artefact for performing a given task, or for representing a real world process or system;
the model artefact that is created, and may be updated by a training process, and which comprises the computational architecture that performs the task; and
the process performed by the model artefact in order to complete the task.
   References to “ML model”, “model”, “model parameters”, “model information”, etc., may thus be understood as relating to any one or more of the above concepts encompassed within the scope of “ML model”.

### BRIEF DESCRIPTION OF THE DRAWINGS

For a better understanding of the embodiments of the present disclosure, and to show how it may be put into effect, reference will now be made, by way of example only, to the accompanying drawings, in which:

FIG. 1a illustrates an example of a HAD beamforming system 100 according to some embodiments;

FIG. 1b illustrates an example scenario for a HAD beamforming system 100 in which a victim wireless device lies in the same direction as an intended wireless device;

FIG. 2a illustrates an example of a DPD module 102a;

FIG. 2b illustrates an example of a combination model 200;

FIG. 3 illustrates a method of performing digital predistortion, DPD;

FIG. 4 illustrates an example of how the combination model may be implemented;

FIG. 5 illustrates an example of a Multi-Layer Perception;

FIG. 6 illustrates an example system for implementing a combined model configured to perform the method of FIG. 3;

FIG. 7 illustrates an example implementation of the system of FIG. 6;

FIG. 8 illustrates an example in which the combination model is implemented as a parallel ML model and MP model;

FIG. 9 illustrates an example implementation of the system of FIG. 4;

FIG. 10 illustrates a method of training a combination model;

FIG. 11a illustrates an example of an indirect learning architecture in which the combination model is trained outside of the signal path;

FIG. 11b illustrates an example of a direct learning architecture in which the combination model is trained outside of the signal path;

FIG. 12 illustrates an DPD module comprising processing circuitry;

FIG. 13 is a block diagram illustrating an DPD module;

FIG. 14 illustrates an DPD module comprising processing circuitry;

FIG. 15 is a block diagram illustrating an DPD module;

FIG. 16 illustrates normalised power spectral density as a function of frequency for signals without DPD, with ML assisted MP based DPD, and with ML based DPD under static traffic conditions;

FIG. 17 illustrates normalised power spectral density as a function of frequency for signals without DPD, with ML assisted MP based DPD, and with ML based DPD under dynamic traffic conditions.

### DETAILED DESCRIPTION

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAS, etc.) and/or using software programs and data in conjunction with one or more digital microprocessors or general-purpose computers. Nodes that communicate using the air interface also have suitable radio communications circuitry. Moreover, where appropriate the technology can additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a complex instruction set computer (CISC), a reduced instruction set computer (RISC), hardware (e.g., digital or analog) circuitry including but not limited to application specific integrated circuit(s) (ASIC) and/or field programmable gate array(s) (FPGA(s)), and (where appropriate) state machines capable of performing such functions.

Machine Learning (ML) approaches for performing or modelling DPD may be considered to be of interest due to the prosperity of ML community. However, traditional decision tree (DT), random forest (RaF), gradient boosting (GB) tree and neural network (NN) based ML methods, have not been studied previously for DPD structures in the context of HAD beamforming M-MIMO. It is noticed that a single ML model cannot handle such challenging issue. Due to this, it will be appreciated that a combination model such as described in embodiments herein may be required.

In contrast, ML approaches proposed on both static traffic (as an idealistic environment) and on dynamic traffic (as a realistic environment) are only currently considered in the context of a single power amplifier. It has been noted that a single ML model cannot handle such challenging issue either.

It will be shown herein that application of ML approaches in a HAD beamforming M-MIMO with both static and dynamic traffic is not straightforward. The resulting performance using only ML approaches cannot meet the requirements on EVM and ACEPR.

Furthermore, ML (e.g. NN) methods together with MP have not been studied previously in the context of PA and DPD behavioral modeling considering wideband and multiband scenarios.

Embodiments described herein therefore propose ML assisted MP based modeling for nonlinear devices, specifically PA and DPD.

Some embodiments described herein utilize ML assisted MP based DPD on beamforming M-MIMO structures. In other words, embodiments described herein utilize both an ML model and an MP model to perform DPD. In some examples, HAD beamforming M-MIMO structures are used. In some examples, digital beamforming M-MIMO structures are used.

Fully digital beamforming, in which a dedicated DPD unit for each transmitter is used, requires huge cost and computational complexity in the base stations and/or wireless devices. HAD beamforming may therefore be preferred as it requires less cost and computational complexity for M-MIMO structures. For HAD beamforming, since the DPD is operating in the digital baseband, a single DPD may linearize all the power amplifiers in an RF chain simultaneously. This is essentially an underdetermined problem and commonly leads to reduced linearization performance for the individual power amplifiers.

When the PA nonlinear characteristics for a number of antennas are assumed to be very similar (which may not be true in the practice), the linearization performance does not decrease significantly. In embodiments described herein, different PA characteristics are considered to be consistent with the practical case, in other words, the power amplifier characteristics are not assumed to be similar.

The embodiments described herein utilizing an ML assisted MP based DPD method result in a robust performance in HAD beamforming M-MIMO under static and dynamic traffic, thanks to the modeling of the different PA characteristics.

As an example, a GB tree assisted MP based approach, which provides a prediction model in the form of an ensemble of weak prediction models, may be considered one of the best performing tree-based ML approaches considered herein. To increase the performance of traditional tree-based methods, boosting as an optimization algorithm on a suitable cost function may be applied.

In general, ML algorithms are designed to work with real-valued signals only. It will be appreciated that the ML model used may therefore first be adapted to handle complex-valued signals.

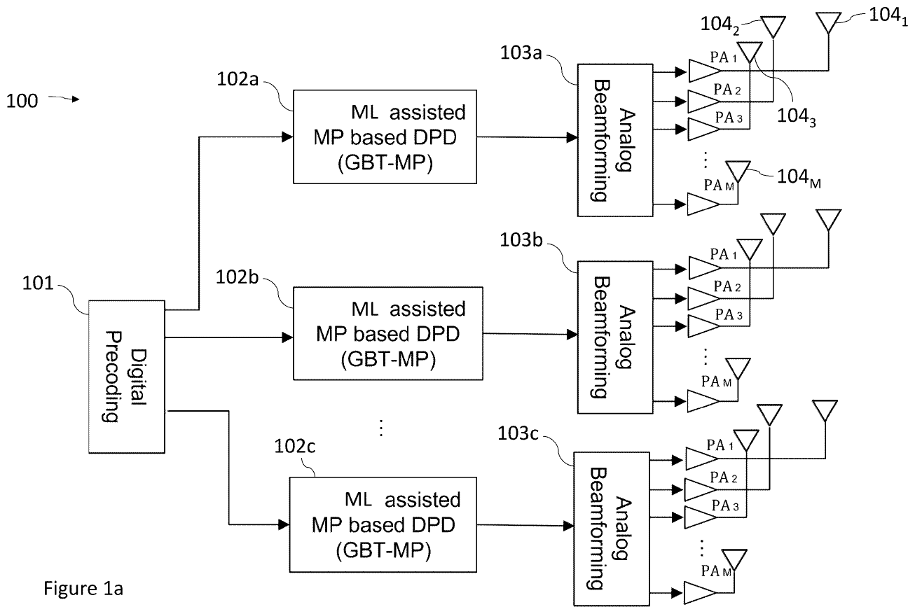

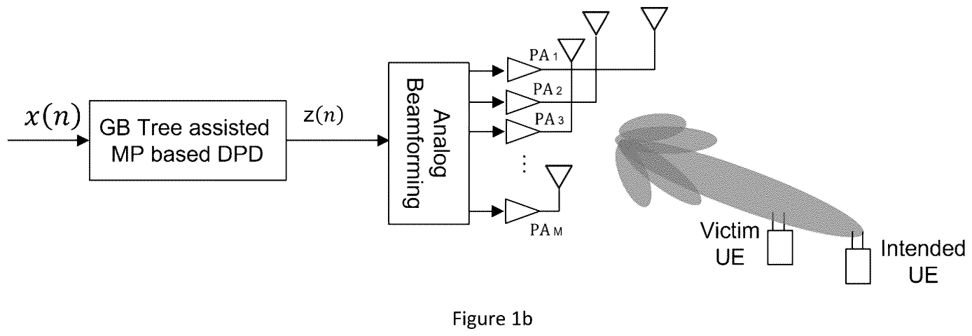

FIG. 1a illustrates an example of a HAD beamforming system 100 according to some embodiments.

The HAD beamforming system comprises a digital precoding module 101 configured to perform precoding.

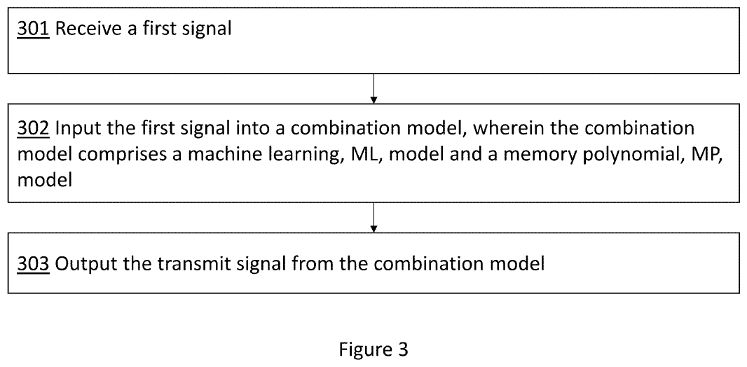

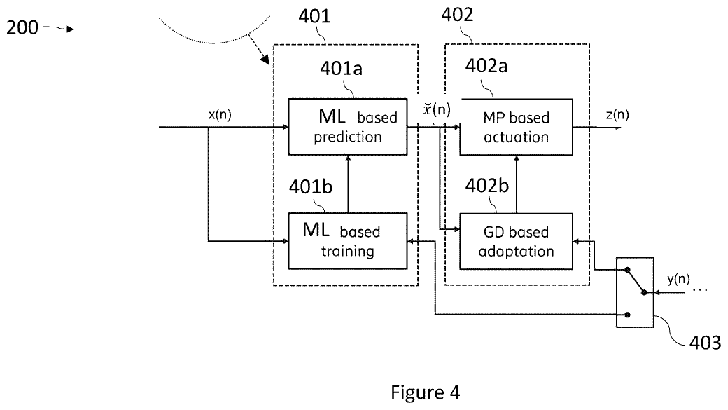

The HAD beamforming system further comprises multiple RF chains, for example three RF chains. Each RF chain comprises a DPD module 102a to 102c according to embodiments described herein. The function of each DPD module 102a to 102c will be described in more detail with reference to FIGS. 3 and 4. The output of each digital beamforming module is used to drive an analog beamforming module 103a to 103c. Each analog beamforming module 103a to 103c then, in turn, drives a plurality of power amplifiers PA₁ to PA_{M} coupled to a plurality of antenna elements 104₁ to 104_{M} (not all numbered for clarity).

FIG. 1b illustrates an example scenario for a HAD beamforming system 100 in which a victim wireless device lies in the same direction as an intended wireless device. For sake of simplicity, only one RF chain and its related components are plotted in the figure. The scenario illustrated in FIG. 1a may be considered as a worst-case scenario and in this example, out-of-band emissions may be similar to the classical emission scenarios and can be quantified using an ACEPR metric. Compensation of the power amplifier nonlinearities with DPD plays a crucial role in HAD beamforming M-MIMO for real life transmissions.

Embodiments described herein therefore make use of a combination model in order to compensate for the power amplifier nonlinearities.

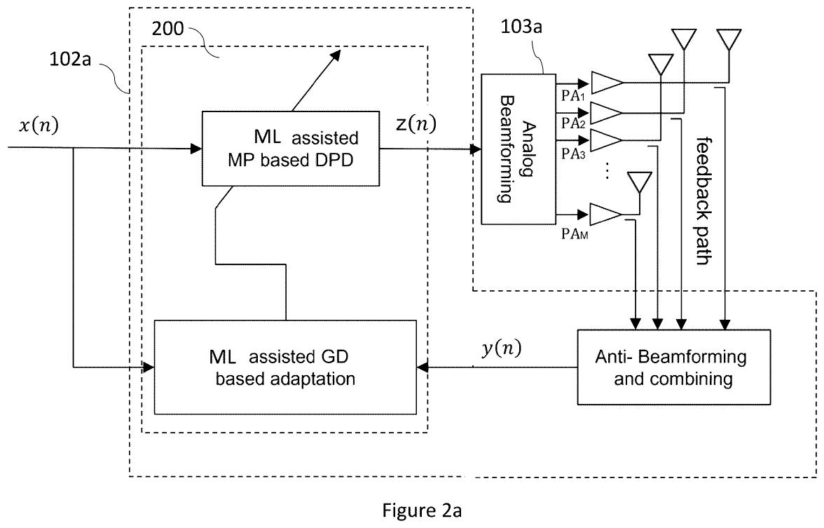

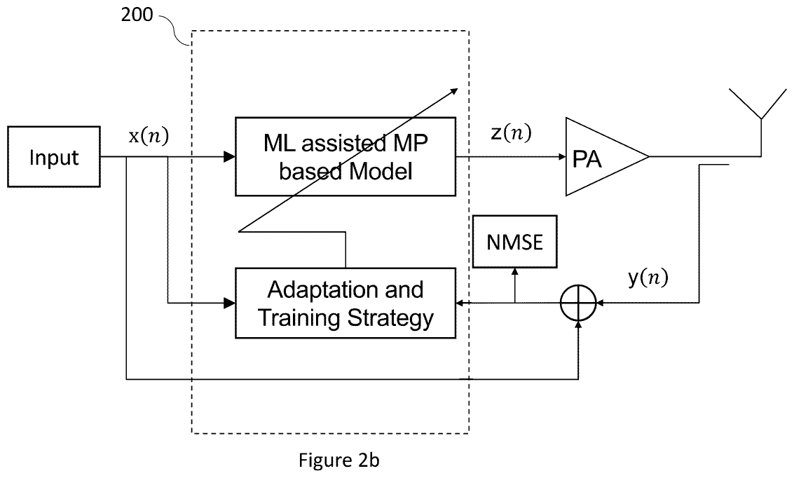

FIG. 2a illustrates an example of a DPD module 102a. It will be appreciated that the DPD modules 102b and 102c illustrated in FIG. 1a may comprise similar features to those described in FIG. 2a with reference to DPD module 102a.

The DPD module 102a comprises a combination model 200. The combination model 200 may be configured to receive a first signal x(n) The combination model 200 may then be trained or adapted based on a feedback signal y(n) and the first signal x(n). The feedback signal y(n) may be derived from an output of the antenna elements which are driven by one or more amplifier signals zₘ(n) derived from a transmit signal z(n) that is output from the combination model 200.

In the example illustrated in FIG. 2a, as HAD beamforming is utilized, the transmit signal is used to derive a plurality of amplifier signals zₘ(n). These amplifier signals zₘ(n) are derived by inputting the transmit signal into an analog beamforming module 103a.

It will be appreciated that the baseband equivalent amplifier signal driving the m-th power amplifier may be expressed as:

zₘ(n)=wₘz(n),

where z(n) comprises the base band equivalent transmit signal output by the combination model 200, wₘ corresponds to the analog beamforming coefficient applied for the m-th antenna element. When |wₘ|=1 it is assumed that no amplitude tapering is performed and only phase rotations are applied in the analog beamforming stage. The beamforming coefficients wₘ may be generally selected so that most of the power is radiated/directed in an intended receiving direction (for example as illustrated later in FIG. 2a).

The baseband equivalent output signal of the m-th power amplifier may be modelled as:

$${y}_{m} ( n ) = {\sum }_{j} {\sum }_{i} F ( \vert {z}_{m} ( n - {d}_{i} ) \vert ) {z}_{m} ( n - {d}_{j} )$$

where F denotes a nonlinear function and dᵢ and dⱼ are memory terms contained in the model. The feedback signal y(n) which may be obtained from the output of the M antenna elements may be expressed as follows:

$$y ( n ) = {\sum }_{m = 1}^{M} {w}_{m}^{*} {y}_{m} ( n ) = M {\sum }_{j} {\sum }_{i} F ( \vert z ( n - {d}_{i} ) \vert ) z ( n - {d}_{j} )$$

FIGS. 1a and 2a illustrate a DPD module 102a being used in a HAD beamforming system. It will however be appreciated that a DPD module 102a according to embodiments described herein may be utilized in a digital beamforming system. In these examples, a DPD module may be provided for each power amplifier, and the amplifier signal zₘ(n), driving the power amplifier may comprise the transmit signal z(n) that is output from the combination model 200.

FIG. 2b illustrates an example implementation of the combination model in which a single power amplifier is driven. It will be appreciated that in some examples, the transmit signal may be utilized to drive only one amplifier.

FIG. 3 illustrates a method of performing digital predistortion, DPD, to provide a transmit signal, z(n), wherein the transmit signal, z(n), is for deriving one or more amplifier signals, zₘ(n), for driving one or more power amplifiers. The method of FIG. 3 may be performed by each DPD module 102a to 102c illustrated in FIG. 1a.

The one or more power amplifiers may be associated with a respective one or more antenna elements.

In step 301 the method comprises receiving a first signal, x(n). The first signal may comprise online or offline training data.

In step 302, the method comprises inputting the first signal, x(n), into a combination model, wherein the combination model comprises a machine learning, ML, model and a memory polynomial, MP, model.

An example of how the combination model may be implemented is illustrated in FIG. 4.

As can be seen in FIG. 4, the combination model 200 comprises a ML model 401 and a MP model 402. It will be appreciated that the ML model 401 may comprise any suitable ML model. For example, the ML model 401 may comprise a tree based ML model (e.g. a decision tree model, a random forest based model or a gradient boosting tree model). In other examples, the ML model 401 may comprise a neural network, NN, based model.

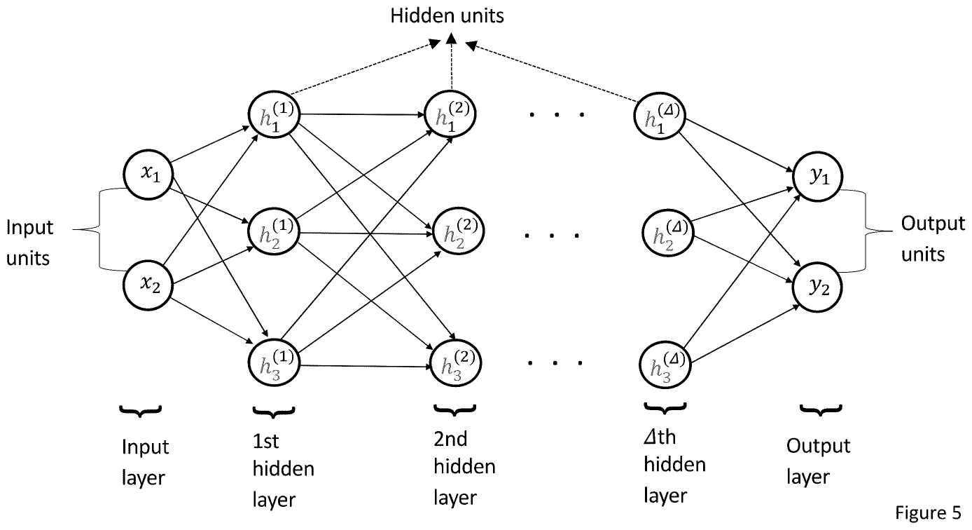

Examples that utilize a NN will be described in more detail with reference to FIGS. 5 to 9.

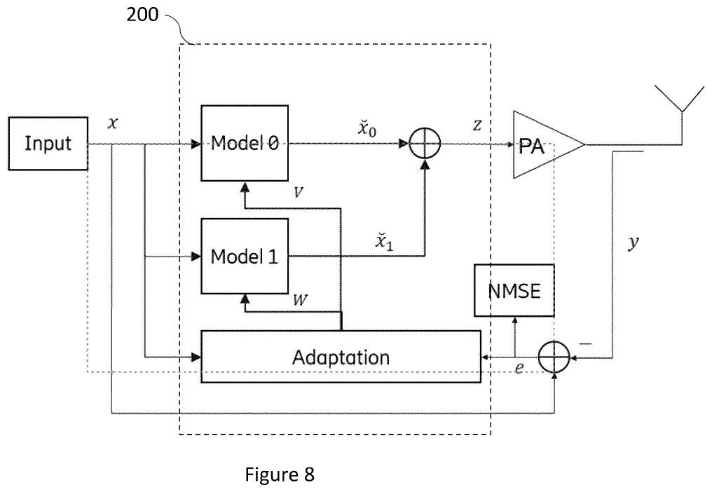

In the example illustrated in FIG. 4, the MP model 402 is configured to receive an output x(n) of the ML model 401. It will however be appreciated that the combination model may be implemented in the reverse order, and the ML model 401 may be configured to receive an output of the MP model. It will also be appreciated that in some examples the combination model may be implemented as a parallel model (for example as illustrated in FIG. 8).

In step 303, the method comprises outputting the transmit signal z(n), from the combination model.

For example, returning to FIG. 4, the ML model 401 may comprise a tree based model. For example, Gradient Boosting Trees (GBT) based prediction 401a may be applied with a coefficient that is updated by using GB based learning 401b. This example is described in more detail below in the section entitled “GBT assisted DPD”.

For the MP model 402, traditional MP based actuation 402a may be applied with a coefficient that is updated by using Gradient Descent (GD) based adaptation 402b. This example is described in more detail below in the section entitled “MP based DPD (Option 1) or (Option 2)”

In other examples the ML model 401 may comprise a neural network mode. While there are several studies on PA and DPD modelling considering narrow and single band scenarios in the literature, wideband and multiband scenarios are only considered with heavy computational complexity and memory resources on only MP based approaches in a few studies. Additionally, there are not any studies that consider NN assisted MP based approaches in wideband and multiband scenarios

NNs are composed of highly interconnected units and each connection of the NN is associated with a weight value which determines the importance of this relationship in the neuron. NN can be categorized to at least three example types based on their structure; i) multilayer perceptron (MLP); ii) radial basis function artificial neural network (RBFNN); and iii) recurrent artificial neural network (RNN).

The most straightforward feed-forward network can be considered as MLP, as seen in FIG. 5 where the units are arranged into a set of layers, and each layer comprises of some number of identical units. In this structure, each unit in one layer is connected to every unit in the other layer which is called as “fully connected”. The first layer is considered as the “input layer”, and its units get the values of the input features. The last layer is considered as the “output layer”, and it has one unit for each value in the network outputs. The layers between first and last layers are called as “hidden layers” which don't include so much information and the computations in these layers are learnt during the learning process. Similarly, the units in above mentioned layers are called as “input units”, “output units”, and “hidden units”, respectively.

The first layer may be expressed as follows:

$$h = φ ( {\sum }_{j} {w}_{j} {x}_{j} + b ) ,$$

where the xⱼ and wⱼ are the inputs to the unit and weights, respectively. b, φ and h are the bias, nonlinear activation function, and unit's activation, respectively.

A NN may be considered as the combination of the several units. In the MLP process considering two layers as the example case, the activations of the input units and activation of the output are considered as xⱼ and y, respectively as with the linear case. The units in the l th hidden layer is defined as

$${h}_{i}^{( l )} .$$

Due to that tne structure is fully connected, each unit is connected to each other (from previous to later layers). This means that each unit includes its own bias, and there is a weight for every pair of units in two consecutive layers. Hence, the network's computations can be expressed as follows:

$${h}_{i}^{( 1 )} = {φ}^{( 1 )} ( {\sum }_{j} {w}_{ij}^{( 1 )} {x}_{j} + {b}_{i}^{( 1 )} ) ,$$

$${h}_{i}^{( 2 )} = {φ}^{( 2 )} ( {\sum }_{j} {w}_{ij}^{( 2 )} {h}_{j}^{( 1 )} + {b}_{i}^{( 2 )} ) ,$$

$${y}_{i} = {φ}^{( 3 )} ( {\sum }_{j} {w}_{ij}^{( 3 )} {h}_{j}^{( 2 )} + {b}_{i}^{( 3 )} ) .$$

For simplicity, the above equations will be written in the vectorized form. The activations of all units are defined with an activation vector, h^{(l)} due of that each layer includes multiple units. Each layer's weights are defined with a weight matrix W^{(l)} because there is a weight for every pair of units in two consecutive layers. Finally, each layer includes a bias vector b^{(l)}.

The above equations may be written in the vectorized form as follows:

$$\\ {h}^{( 1 )} = {φ}^{( 1 )} ( {\sum }_{j} {W}^{( 1 )} x + {b}^{( 1 )} ) , {h}^{( 2 )} = {φ}^{( 2 )} ( {\sum }_{j} {W}^{( 2 )} {h}^{( 1 )} + {b}^{( 2 )} ) , y = {φ}^{( 3 )} ( {\sum }_{j} {W}^{( 3 )} {h}^{( 2 )} + {b}^{( 3 )} ) .$$

When all the training examples are combined into a single matrix X, all the predictions using a single matrix multiplication can be calculated. It can be possible to have all of each layer's hidden units for all the training examples as a matrix H^{(l)}. The above equations can therefore be rewritten as follows:

H⁽¹⁾=φ⁽¹⁾(XW^{(1)†}+1b^{(1)†}),

H⁽²⁾=φ⁽²⁾(H⁽¹⁾W^{(2)†}+1b^{(2)†}),

Y=φ⁽³⁾(H⁽²⁾W^{(3)†}+1b^{(3)†}).

It is noted that † and I are corresponding to the transpose operation and identity matrix, respectively. The following sections describe methods for performing training of different types of models.

### GB Tree Assisted DPD

As described above, the ML model 401 part of the combination model 200 may implement GB Tree based prediction and GB based training/learning to improve the performance of DPD on HAD beamforming M-MIMO.

Traditional decision trees, which may be considered as one of the tree-based ML approaches that performs both classification and regression, can separate the input space into different dimensions. The traditional decision trees only consider real values of the input signals. It will be appreciated that the model may require extension to support complex values. A straightforward modification may be to split the real and imaginary parts of the samples and feed them separately. Meanwhile, the memory effects of the PA need to be considered carefully. With this process, the model output signals can be dependent on not only the current input signals, but also the previous input signals.

Using a single DT, only a few critical features may be applied, and due to this, full characterization of the power amplifier behaviour may not be achieved. To overcome this disadvantage of traditional DT based ML methods, GB regression-based ML techniques may be used, which increases the linearization performance in DPD, and may be defined as an ensemble of DTs. GB techniques predicts the desired output based on the additive regression model which uses a DT as a weak learner fitting of a parameterized function to current “pseudo”-residuals. A GB based ML approach is applied at each iteration by optimizing regression loss such as absolute error instead of having one tree. “Pseudo” residuals may be described as the minimization of the gradient of a loss function with respect to values of the regression model at each training data set for the current step. Due to the randomization in the process of training data set selection, this GB based ML approach improves the accuracy and also reduces the possibility of overfitting. The implementation of the modified/improved version of DT may minimize the errors at each next step, and therefore the GB based ML approach may be considered as more reliable and robust compared to a traditional DT regressor.

A common regression problem may be expressed as follows:

Given N training data D={(x₁, y₁), (x₂, y₂) . . . (x_{N}, y_{N})}, in which xⱼ belongs to a set χ⊂ [symbol] ^{m} and represents a feature vector involving m features, and y; ∈ [symbol] represents the observed output or the target value such that yᵢ=ƒ(xᵢ)+ε. Here, ε is the error (non-linear distortion) with expectation of a small value such as 0 and unknown finite variance.

The ML targets to construct a regression model or an approximation g of the function ƒ that minimizes:

$$\\ L ( f ) = {𝔼}_{( x , y ) \sim P} l ( y , g ( x ) ) = {\int }_{{𝒳}^{𝓍 ℝ}} l ( y , g ( x ) ) dT ( x , y ) ,$$

with respect to the function parameters. Here T(x,y) is a joint probability distribution of x and y; and the loss function ƒ(.,.) can be represented as follows

l(y,g(x))=(y−g(x))².

Specifically, GB regression, which is one of the powerful ML algorithms, is an iterative process of a model as an ensemble of base prediction models built in a stage-wise fashion where each base model is constructed, based on data obtained using an ensemble of models already built on previous iterations, as an approximation of the loss function derivative. A model of size Ω is a linear combination of Ω base models:

$$\\ {g}_{Ω} ( x ) = {{\sum }_{i = 0}}^{Ω} {y}_{i} {h}_{i} ( x )$$

where hᵢ is the i-th base model; γᵢ is the i-th coefficient or the i-th base model weight.

The GB algorithm may be explained with the following steps:
1. Initialize the zero-base model hₒ(x), for instance, with a constant value.
2. Compute the residual rᵢ^{(t)} as a partial derivative of the expected loss function L(xᵢ, yᵢ) at each point of the training data-set, i=1, 2 . . . . N.
3. Build the base model hₗ(x) as regression on residuals {(xᵢ, rᵢ^{(t)})}
4. Obtain the optimal coefficient γₜ at hₜ(x) with respect to the initial expected loss function;
5. Update the entire model gₜ(x)=gₜ₋₁(x)+γₗhₜ(x);
6. If the value does not reach the stop criteria, move to step 2.

The loss function depends on the ML problem solved. Assume that (Ω−1) steps produce the model g_{Ω-1}(x). The model h_{Ω}(x) may be built for constructing the model g_{Ω}(x) as follows:

$$\\ {g}_{Ω} ( x ) = {{\sum }_{t = 1}}^{Ω} {y}_{t} {h}_{t} ( x ) = {g}_{Ω - 1} ( x ) + {γ}_{Ω} {h}_{Ω} ( x ) .$$

The data-set for building the model h_{Ω}(x) may be selected to approximate the expected loss function partial derivatives with respect to the function of the previously constructed model g_{Ω-1}(x). The residuals rᵢ^{(Ω)} may be determined as the values of the loss function partial derivative at point g_{Ω-1}(xᵢ) in the current iteration Ω,

$${\\ {r}_{i}^{( Ω )} = - \frac{\partial L ( z , {y}_{i} )}{\partial z} \vert}_{z = {g}_{Ω - 1} ( {x}_{i} )}$$

By applying the residuals, a new training set D_{Ω} may be calculated as follows:

$$\\ {D}_{Ω} = {\{ ( {x}_{i} , {r}_{i}^{( Ω )} ) \}}_{i = 1}^{N}$$

and the model h_{Ω} may be built on D_{Ω} by solving the below optimization:

$$\\ min {\sum }_{i = 1}^{N} {‖ {h}_{Ω} ( {x}_{i} ) , {r}_{i}^{( Ω )} ‖}^{2} .$$

Therefore, an optimal coefficient γ_{Ω} of the gradient descent may be calculated as:

$$\\ {γ}_{Ω} = arg {min}_{γ} {{\sum }^{N}}_{i = 1} L [ {g}_{Ω - 1} ( x ) + γ {h}_{Ω} ( {x}_{i} ) , {y}_{i} ] .$$

Finally, following the model at every point xᵢ of the training set can be expressed as follows:

$${\\ {g}_{Ω} = {g}_{Ω - 1} ( x ) + {γ}_{Ω} {h}_{Ω} ( x ) \approx {g}_{Ω - 1} ( x ) - {γ}_{Ω} \frac{\partial L ( z , {y}_{i} )}{\partial z} \vert}_{z = {g}_{Ω - 1} ( {x}_{i} )}$$

Which is related to the residuals

$${\\ {r}_{i}^{( Ω )} = - \frac{\partial L ( z , {y}_{i} )}{\partial z} \vert}_{z = {g}_{Ω - 1} ( {x}_{i} )} .$$

A cost function may comprise a quadratic function which is differentiable with respect to the input argument.

For example, the cost function may be as follows:

L(z,yᵢ)=(z−yᵢ)².

In this example the derivative of the cost function may be given as:

$$\\ \frac{\partial L ( z , {y}_{i} )}{\partial z} = 2 z ( z - {y}_{i} ) .$$

It will be appreciated that, except in the case of some special functions, it is not difficult to calculate the derivative of most functions in practice.

The algorithm as described above minimizes the expected loss function by applying decision trees as base models. The parameters of the Gradient Boosting (GB) based approach above may comprise for example: depths of trees, a learning rate, and/or a number of iterations. These parameters may be experimentally tested to provide the best performance. The GB method may be considered a powerful and efficient method to solve regression problems, which can cope with complex non-linear function dependencies.

### MP Based DPD (Option 1)

Memory polynomials (MP) may be used as a foundation of parametric models for linearization of power amplifiers. The transmit signal may be expressed as:

$$\\ z ( n ) = {{\sum }_{i = 0}}^{I - 1} {{\sum }_{p = 0}}^{\frac{P}{2} - 1} {a}_{i , p} {\vert x ( n - {D}_{i} ) \vert}^{2 p} x ( n - {D}_{i} )$$

To handle additional cross memory terms in wideband signal, generalized MP (GMP) is presented as well, whose expression is given by:

$$\\ z ( n ) = {{\sum }_{j = 0}}^{J - 1} {{\sum }_{i = 0}}^{I - 1} {{\sum }_{p = 0}}^{\frac{P}{2} - 1} {a}_{i , j , p} {\vert x ( n - {D}_{i} ) \vert}^{2 p} x ( n - {D}_{j} )$$

Where α_{i,j,p} (α_{i,p} in MP) denotes the coefficient of GMP model, P denotes the polynomial order, and Dᵢ and denote the tap delays, respectively.

Basically, an MP model (which as previously discussed may refer to an MP or a GMP model) may be considered to provide excellent performance for a single power amplifier with static traffic.

In the meantime, thanks to its low cost of implementation, MP based DPD has been recognized as a popular model for linearization of a nonlinear power amplifier. However, in the context of HAD beamforming, since M branches of power amplifiers are linearly combined with corresponding beam coefficients, the resulting behavior is a challenge for MP based DPD.

Compared to linearization of single power amplifier, an MP model suffers from performance degradation in the linearization of combined power amplifiers. Furthermore, dynamic traffic is also a headache for MP based DPD. Normally, an MP model is good at characterization of nonlinear behavior in a small (amplitude) dynamic range. Greater (amplitude) dynamic ranges, however, reduce the accuracy of MP models. Unfortunately, dynamic traffic is unavoidable practically in the operating network.

The coefficient of MP model, i.e. α_{i,j,p} (α_{i,p} in MP) is computed by a gradient descent (GD) algorithm. The purpose of adaptation of the MP model may be understood as minimizing the cost function derived from the feedback signal y(n) and the first signal x(n). The GD algorithm may be expressed as:

$$\\ {a}_{i , j , p}^{l + 1} = {a}_{i , j , p}^{l} - μ ∇ J ( {a}_{i , j , p}^{l} )$$

where μ is the step size. μ may be selected such that the converging rate and residual error are balanced.

A cost function J(α_{i,j,p}) may be defined as:

$$\\ J ( {a}_{i , j , p} ) = {\sum }_{n} {\vert x ( n ) - y ( n ) \vert}^{2}$$

The gradient ∇J(α_{i,j,p}) denotes the partial derivative of J(α_{i,j,p}) with respect to α_{i,j,p}, which is given by:

$$∇ J ( {a}_{i , j , p} ) = M {\sum }_{n} {\vert x ( n - {D}_{i} ) \vert}^{2 p} x ( n - {D}_{j} ) * ( x ( n ) - y ( n ) )$$

Eventually, the cost function will converge to the minimum value.

### MP Based DPD (Option 2)

MP is the foundation of parametric models for characterization of nonlinear behaviors with memory effects, which can be expressed as

$$z ( n ) = {\sum }_{i = 0}^{I - 1} {\sum }_{p = 0}^{\frac{P}{2} - 1} {a}_{i , p} {\vert x ( n - {D}_{i} ) \vert}^{2 p} x ( n - {D}_{i} ) .$$

To handle additional cross memory terms in wideband and multiband signals, GMP extends MP by adding some extra terms, that is

$$z ( n ) = {\sum }_{i = 0}^{I - 1} {\sum }_{p = 0}^{\frac{P}{2} - 1} {a}_{i , p} {\vert x ( n - {A}_{i} ) \vert}^{2 p} x ( n - {D}_{i} ) .$$

Where α_{i,p} denotes the coefficient of GMP model, and P denotes the polynomial order, Aᵢ and Dᵢ denote address and data delays, respectively. These names are originated from the implementation of GMP models. It is seen that the output data z(n) is the sum of multiplications of the input data x(n−Dᵢ) with nonlinear coefficient α_{i,p}|x(n−Aᵢ)|^{2p}. The nonlinear coefficient is stored as a lookup-table and its address is indexed by |x(n−Aᵢ)|. For this reason, Aᵢ is referred to as address delay, and Dᵢ is referred to as data delay.

In the baseline algorithms such as GMP, it may be needed to have the proper optimal address and data delays in the mathematical equations for obtaining the good modelling performance. Address and data delays are also called as tap delays herein and in most scientific articles.

Basically, MP has excellent performance for single PA with narrow single band with the optimal address and data delays. In the meantime, thanks to its low cost of implementation, MP based PA and DPD modelling has been recognized as the most popular one. However, in the context of wideband and multiband scenarios under optimal address and data delays, the resulting behavior is a challenge for MP based PA and DPD modelling.

The coefficient of a MP model, i.e. α_{i,p}, may be computed by a GD algorithm. The purpose of adaptation is to minimize the cost function derived from the first signal x(n) and the feedback signal y(n).

Here, defining the cost function as J=Σₙ|e(n)|²=Σₙ|x(n)−y(n)|², the coefficient calculation by GD algorithm can be written as

$${a}_{imp}^{( l + 1 )} = {a}_{i , p}^{( l )} - μ ∇ J ( {a}_{i , p}^{( l )} ) ,$$

where, μ is step size. A proper μ may be selected to balance converging rate and residual error.

$${a}_{i , p}^{( l )} and {a}_{i , p}^{( l + 1 )}$$

denote the coefficient at (l) and (l+1) iteration, respectively

$$∇ J ( {a}_{i , p}^{( l )} )$$

is the gradient of cost function with respect to the coefficient

$${a}_{i , p}^{( l )} .$$

Here, we define the output of filter tap i as

$${z}_{i} ( n ) = {\sum }_{p = 0}^{\frac{P}{2} - 1} {a}_{i , p} {\vert x ( n - {A}_{i} ) \vert}^{2 p} x ( n - {D}_{i} ) .$$

Therefore, the MP model can be rewritten as

$$z ( n ) = {\sum }_{i} {z}_{i} ( n ) .$$

For sake of simplicity, only the real value in the derivation of the gradients may be considered. Extending to complex values may be straightforward. Additionally, as the PA model is unknown, it may be assumed that the derivative of PA output with respect to PA input is linear. According to the chain rule, the gradient of the cost function may be expressed as:

$$∇ J ( {a}_{i , p}^{( l )} ) = \frac{\partial J}{\partial {a}_{i , p}^{( l )}} = {\sum }_{m} \frac{\partial J}{\partial z ( m )} {\sum }_{i} \frac{\partial {z}_{i} ( m )}{\partial {a}_{i , p}^{( l )}} = 2 {\sum }_{m} e ( m ) {\sum }_{i} {\vert x ( m - {A}_{i} ) \vert}^{2 p} x ( m - {D}_{i} ) .$$

On the other hand, to support backpropagation in cascade structure, the gradient of cost function with respect to model input signal x(n) may also be needed to feedback to the ML model. For example, the MP model may be configured to receive the output of the ML model x(n) as its input signal. This gradient may be expressed as:

$$∇ J ( \breve{x} ( n ) ) = \frac{\partial J}{\partial \breve{x} ( n )} = {\sum }_{m} \frac{\partial J}{\partial z ( m )} {\sum }_{i} \frac{\partial {z}_{i} ( m )}{\partial \breve{x} ( n )} = 2 {\sum }_{m} e ( m ) {\sum }_{i} \frac{\partial {z}_{i} ( m )}{\partial \breve{x} ( n )} .$$

can be given by

$$\frac{\partial {z}_{i} ( m )}{\partial \breve{x} ( m )} = \{ \begin{matrix}\begin{matrix}{\sum }_{p = 0}^{\frac{P}{2} - 1} {a}_{i , p} ( 2 p {\vert \breve{x} ( n - {A}_{i} ) \vert}^{2 p - 1} ) \\ sign ( \breve{x} ( n - {A}_{i} ) ) \breve{x} ( n - {D}_{i} ) ,\end{matrix} & m = n - {A}_{i} \\ {\sum }_{p = 0}^{\frac{P}{2} - 1} {a}_{i , p} {\vert \breve{x} ( n - {A}_{i} ) \vert}^{2 p} , & m = n - {D}_{i} \\ 0 , & otherwise\end{matrix} .$$

Where, sign (x̌(n−Aᵢ)) is the sign of x̌(n−Aᵢ).

Generally,

$$\frac{\partial {z}_{i} ( m )}{\partial \breve{x} ( n )}$$

may comprise a Jacobian matrix that has N columns by N rows, wherein N denotes the number of samples, e.g. N=4096 samples used in one DPD iteration. n=1, . . . . N, denotes the index of rows, m=1, . . . , N, denotes the index of columns. However, Aᵢ and Dᵢ are the address delay and data delay for filter tap i. They may comprise scalar numbers and may be configured by developers in the production integration. For example, Aᵢ=1, Dᵢ=2 and these numbers may not be changed unless a new carrier type is activated. As a result, m, n and Aᵢ and Dᵢ may not be merged.

In examples where the ML model receives the output of the MP model x̌(n) as an input, the MP model may receive the gradient

$$\frac{\partial J}{\partial \breve{x} ( m )}$$

as a feedback gradient (i.e. from the output layer of the ML model). The gradient for updating the MP model may then be calculated as:

$$∇ J ( {a}_{i , p}^{( l )} ) = \frac{\partial J}{\partial {a}_{i , p}^{( l )}} = {\sum }_{m} \frac{\partial J}{\partial \breve{x} ( m )} {\sum }_{i} \frac{\partial {\breve{x}}_{i} ( m )}{\partial {a}_{i , p}^{( l )}}$$

### Neural Network Assisted DPD

To derive the gradient descending in the adaptation process for NN based approach, the

$$\frac{\partial J}{\partial {b}_{i}^{( l )}} = \frac{\partial J}{\partial {h}_{i}^{( l )}} \frac{\partial {h}_{i}^{( l )}}{\partial {t}_{i}^{( l )}} \frac{\partial {t}_{i}^{( l )}}{{\underbrace{\partial {b}_{i}^{( l )}}}_{1}} = ∇ J ( {h}_{j}^{( l )} ) {φ}^{′} ( {t}_{i}^{( l )} ) = \frac{\partial J}{\partial {t}_{i}^{( l )}} .$$

$$\frac{\partial J}{\partial {W}_{ij}^{( l )}} = \frac{\partial J}{\partial {h}_{i}^{( l )}} \frac{\partial {h}_{i}^{( l )}}{\partial {t}_{i}^{( l )}} \frac{\partial {t}_{i}^{( l )}}{{\underbrace{\partial {W}_{ij}^{( l )}}}_{{h}_{j}^{( l - 1 )}}} = ∇ J ( {h}_{j}^{( l )} ) {φ}^{′} ( {t}_{i}^{( l )} ) {h}_{j}^{( l - 1 )} ,$$

$$∀ i = 1 , 2 , 3 … {U}^{( l )} .$$

Where the partial derivatives of

$${t}_{i}^{( l )}$$

with respect to

$${W}_{ij}^{( l )} and {b}_{i}^{( l )}$$

can be directly derived.

Similarly, the chain rule may be used to compute the partial derivative of/with respect to the post-activation hidden unit

$${h}_{j}^{( l - 1 )}$$

for layer (l−1). It is noted that J depends on

$${h}_{j}^{( l - 1 )}$$

via all of the pre-activation hidden units

$${\{ {t}_{i}^{( l )} \}}_{i = 1}^{{U}^{( l )}}$$

in layer l; hence the gradient may be backpropagated through the layers as follows:

$$∇ J ( {h}_{j}^{( l - 1 )} ) = \frac{\partial J}{\partial {h}_{j}^{( l - 1 )}} = {\sum }_{j} \frac{\partial J}{\partial {h}_{i}^{( l )}} \frac{\partial {h}_{i}^{( l )}}{\partial {t}_{i}^{( l )}} {\underbrace{\frac{\partial {t}_{i}^{( l )}}{\partial {h}_{j}^{( l - 1 )}}}}_{{W}_{ij}^{( l )}} = {\sum }_{j} \frac{\partial J}{\partial {h}_{i}^{( l )}} {φ}^{′} ( {t}_{i}^{( l )} ) {W}_{ij}^{( l )} , \\ ∀ j = 1 , 2 , 3 … {U}^{( l - 1 )} .$$

It will be appreciated that

$$\frac{\partial J}{\partial {h}_{i}^{( l )}}$$

is the output layer derivative of the cost function. When the MP model is configured to receive an output of the ML model this gradient may comprise a feedback gradient received from the MP model. Similarly when the ML model is configured to receive an output of the MP model, the gradient

$$\frac{\partial J}{\partial {h}_{i}^{( 1 )}}$$

may be received at the MP model from the ML model as a feedback gradient.

### Training Strategies

In the above sections, the training of the MP model and the ML model is discussed, respectively. However, for the cascading structure or the parallel structure of the combination model 200 as described in FIG. 4, there may be several strategies for training the whole combination model 200.

In some examples, partial derivatives of the cost function with respect to the parameters may be calculated via back-propagation, so that the whole combination model 200 may be trained simultaneously.

### Training by Backpropagation

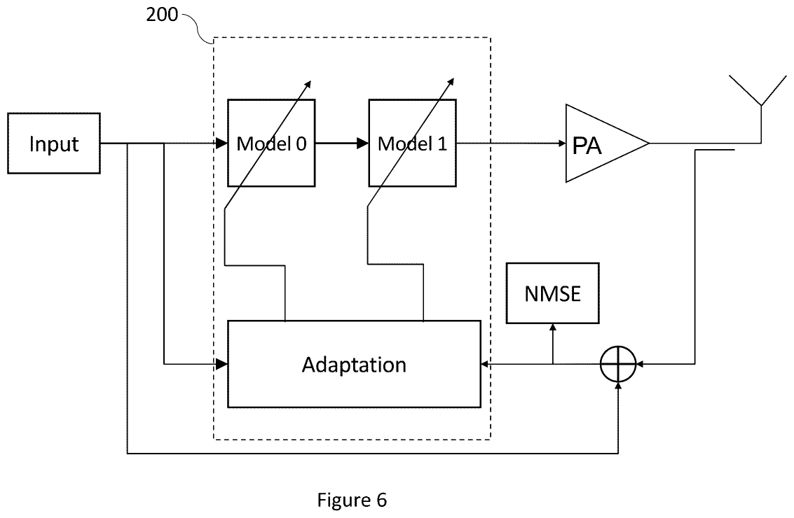

FIG. 6 illustrates an example system for implementing a combination model configured to perform the method of FIG. 3.

In this example, the combination model 200 is implemented as a cascade of the model 0 and model 1. It will be appreciated that in some examples, model 0 comprises an ML model (e.g. GB Tree or NN) and model 1 comprises an MP model. Alternatively, the model 0 comprises the MP model and the model 1 comprises the ML model.

In this example both models may be continuously trained and backpropagation may be implemented between the models.

To train the combination model a cost function is determined based on the first signal x(n) and the feedback signal y(n). For example, the cost function may be determined as: J=Σₙ|e(n)|²=Σₙ|x(n)−y(n)|².

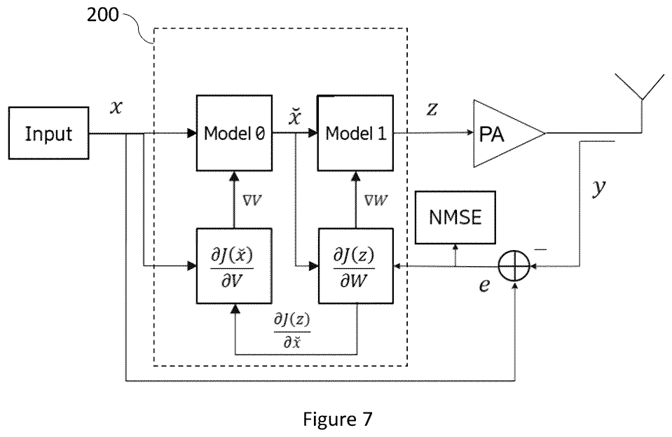

FIG. 7 illustrates an example implementation of the system of FIG. 6.

Consider firstly an example in which model 1 comprises an MP model and the model 0 comprises a ML model (e.g. a NN). It will be appreciated that the MP model may be trained as described in either section “MP based DPD (Option 1)” or section “MP based DPD (Option 2)” above. The ML model may be trained as described in either section “NN assisted DPD” or section “GB Tree assisted DPD” above.

In this example, the MP model is configured to receive an output of the ML model.

To train the MP model therefore, gradient descent (indicated by VW in FIG. 7) may then be performed on the MP model utilizing a partial derivative of the cost function with respect to a coefficient of the MP model (e.g.

$$∇ J ( {a}_{i , p}^{( l )} )$$

as described above in the section “MP based DPD (Option 2)”.

To train the ML model, a feedback gradient may be determined by determining a derivative of the cost function with respect to the output of the ML model (e.g. ∇J(x̌(n)) as described above in the section “MP based DPD (Option 2)”.

To train the ML model gradient descent (indicated by VV in FIG. 7) may then be performed utilizing one or more partial derivatives of the cost function with respect to one or more respective parameters of the ML model. These partial derivatives may be determined using the feedback gradient as described above in the section “NN assisted DPD” above. When the ML model comprises a NN, the respective parameters of the ML model may comprise the weights and bias vectors of the NN.

In other examples, the model 1 comprises the ML model (e.g. a NN) and the model 0 comprises the MP model. In these examples, the ML model is configured to receive an output of the MP model.

In some examples, the backpropagation of a feedback gradient from an ML model to an MP model may occur in the same way as described above.

However, in examples in which the ML model comprises a neural network the ML model may be trained by performing gradient descent (VW) utilizing one or more partial derivatives of the cost function with respect to one or more respective parameters of the neural network. The respective parameters of the NN may comprise the weights and bias vectors of the NN.

To train the MP model, gradient descent (VV) may then be performed utilizing a partial derivative of the cost function with respect to a coefficient of the MP model. In this example, the partial derivative of the cost function is determined based on a feedback gradient received from the input layer of the ML model.

FIG. 8 illustrates an example in which the combination model is implemented as a parallel ML model and MP model. In other words, in this example, the MP model and the ML model both receive the first signal, x(n). The transmit signal, z(n) is derived from a first intermediate signal output from the MP model and a second intermediate signal output from the ML model. The first and second intermediate signals are indicated as x₀ and x₁ in FIG. 8.

Similarly to as described above either the model 0 comprise the ML model and the model 1 comprise the MP model or the model 0 comprise the MP model and the model 1 comprises the ML model.

For example, the transmit signal z(n) may comprise a sum of the first intermediate signal and the second intermediate signal.

To train the MP model gradient descent may then be performed utilizing a partial derivative of the cost function with respect to the first intermediate signal. To train the ML model gradient descent may be performed utilizing a partial derivative of the cost function with respect to the second intermediate signal.

In other words, the gradient for each of model 0 and model 1 can be expressed as,

$$\frac{\partial J}{\partial {{x}^{⌣}}_{0} ( n )} = \frac{\partial J}{z ( n )} ,$$

$$\frac{\partial J}{\partial {{x}^{⌣}}_{1} ( n )} = \frac{\partial J}{z ( n )} .$$

The two models may be updated simultaneously according to predefined step size. It is noted two models may have different step sizes to exploit their capability in more efficient way.

Considering the different computational complexities for training the MP model and the ML model, an alternative may be to train the two models separately such that one model is being trained whilst training of the other model is disabled. This is illustrated in the example of FIG. 4. In this example, the switching box 403 may alternatively feed the error signal to either the ML model or the MP model.

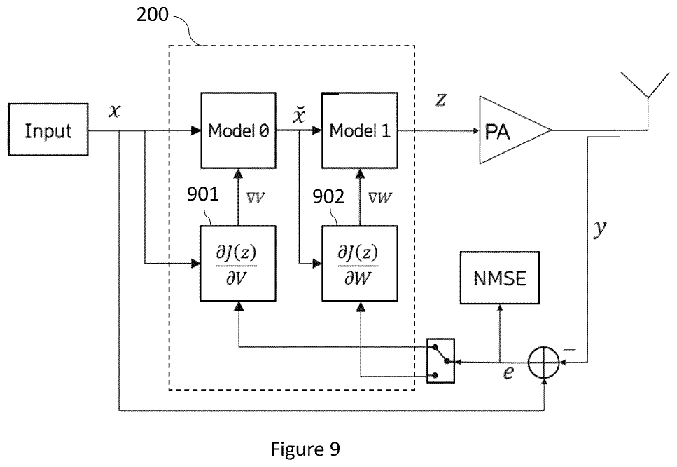

FIG. 9 illustrates an example implementation of the system of FIG. 4. In this example the boxes for determination of the gradients for gradient descent are illustrated (901 and 902). In contrast to the system illustrated in FIG. 7, the gradients for both models are calculated based on the error signal e(n), and there is no feedback gradient passed between the two models.

It will be appreciated that the updating of the ML model and the MP model may be based on the received feedback signal y(n), and the first signal x(n). For example, the updating may be based on an error signal e(n) derived from the feedback signal y(n), and the first signal x(n).

In the first strategy, MP model and ML model are updated periodically and alternately. For example, odd number iterations, the MP model is updated, while in even number iterations, the ML model is updated.

In some examples therefore the method of FIG. 3 further comprises, during a first time period, performing training of the ML model using the feedback signal, y(n) and the first signal x(n); and during the first time period disabling training of the MP model.

Similarly, the method of FIG. 3 may further comprise, during a second time period, performing training of the MP model using the feedback signal, y(n) and the first signal x(n); and during the second time period disabling training of the ML model.

In some examples, the method of FIG. 3 comprises training the MP model and the ML model using the feedback signal y(n) and the first signal x(n) by performing periodic and alternate updates to the MP model and the ML model.

In the second strategy, the MP model or ML model may be updated responsive to a request from a DPD controller. The DPD controller may be comprised in an application specific integrated circuit (ASIC) or field programmable gate array (FPGA) in a radio unit of a base station or a component in a user equipment. A software DPD controller may be implemented in a central processing unit (CPU) built on a Complex Instruction Set Computer (CISC), Reduced Instruction Set Computer (RISC) or advanced RISC machine (ARM).

For example, the method of FIG. 3 may comprise triggering the start of the first time period in response to a request to update the ML model. The request to update the ML model may for example occur only once during carrier setup. The ML model may then be frozen after carrier setup unless a new request is received.

The method of FIG. 3 may further comprise triggering the start of the second time period in response to a request to update the MP model. The request to update the MP model may for example be requested occasionally to handle other effects.

In some examples, the update of the MP model may be requested only once during the carrier setup and thereafter the MP model may be frozen after carrier setup unless a new request is received. In the meantime, the update of the ML model may be requested to work occasionally to handle other effects.

The second strategy may require intervention and signaling from the DPD controller. Therefore, compared to the first strategy, the second strategy comprises extra overhead in signaling. However, the second strategy is more flexible than the first strategy, and more power efficient, because the training algorithms are enabled or disabled on demand.

Additionally, the ML model and the MP model may be trained either offline and/or online.

In offline training, the ML model may be completed offline in the different periods such as once in a week, month, year, and the saved network may be used for prediction considering any test signals. Because of the less complex implementation, the prediction may be completed with the saved data with online implementation. Alternatively, both the training and prediction may be online.

It will be appreciated that DPD models are relevant to either the input signal's statistics or the power amplifiers behavioral characteristics.

In the example illustrated in FIGS. 4 and 9, during training of the ML model the power amplifiers characteristics have been corrected by the MP model in the last iteration. Updating the ML model may then be to accommodate any new behavior caused by the combined effects of the MP model and the power amplifier.

In the training of MP model, the input signal's statistics has been modified by the ML model in the last iteration. Updating MP model may then be to accommodate the new input statistics that consider the modification of ML model in the input signal.

If the training is completed once in a month, half year or a year based on the environmental change, ML based prediction with saved network from training process is enough. In this way, power saving in other mean energy efficiency can be achieved.

Additionally, a power feature extraction process may be applied on ML assisted MP based DPD on HAD beamforming M-MIMO to obtain improved performance under both the static and dynamic traffic conditions.

This power feature extraction process, which may be applied in the ML assisted MP based DPD approach, is an additional process to successfully compensate the dynamic traffic effects on HAD beamforming M-MIMO structures.

The power feature extraction process may comprise utilizing one or more of: a moving-average (MA) filter, an exponential moving-average (EMA) filter, an autoregressive (AR) filter, an autoregressive moving-average (ARMA) filter and a symbol-based (SB) filter.

Based on the input from the power feature extraction stage, a different label may be applied to finalize the power feature extraction process.

The embodiments described herein achieve very high DPD compensation performance (as will be illustrated below in the section entitled “Simulation Results”) with less required memory (hardware) resources, and lower power consumption for HAD beamforming M-MIMO. It increases in the degrees of freedom in the DPD and, at the same time, more diversity in the basis functions.

Ideal input signals and the output of GD based adaptation for the MP model are complex and the complex data may be directly applied in the MP model. However, the ML model may naturally work with only with real-valued signals. Hence, it may firstly be necessary to convert a complex-valued first signal x(n) into a real signal in a matrix format considering also memory stages in the ML model.

Additionally, the embodiments described herein may be considered to be low power and provide a high energy efficiency due to their simplicity, especially in the HAD beamforming M-MIMO embodiments.

This low power consumption and high energy efficiency may be because, instead of a single large-scale MP model with numerous polynomial terms and memory terms, the proposed approach increases the degrees of freedom in the modelling by employing GB based ML model, and at the same time, creates more diversity in the basis functions. Hence, the proposed ML assisted MP based method achieves very high modeling accuracy with less required memory (hardware) resource, as well as lower power consumption on HAD beamforming M-MIMO structure.

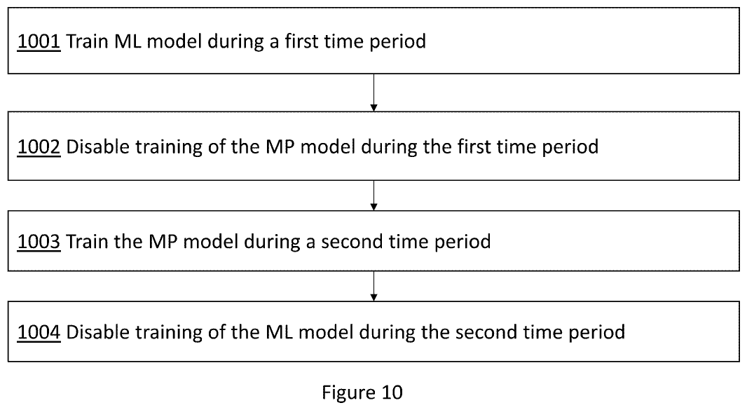

FIG. 10 illustrates a method of training a combination model for performing digital predistortion to provide a transmit signal, z(n), wherein the transmit signal, z(n), is for deriving one or more amplifier signals, zₘ(n), for driving one or more power amplifiers, wherein the one or more power amplifiers are associated with a respective one or more antenna elements. The combination model comprises a ML model and a MP model, for example as illustrated in FIG. 4. It will be appreciated that the method of FIG. 10 may be performed using online data, offline data, or a combination of both online data and offline data (as described above).

In step 1001 the method comprises training ML model during a first time period.

In step 1002 the method comprises disabling training of the MP model during the first time period.

In step 1003 the method comprises training the MP model during a second time period.

In step 1004 the method comprises disabling training of the ML model during the second time period.

The method of FIG. 10 may further comprise receiving a feedback signal, y(n), based on an output of the one or more power amplifiers (for example as illustrated in FIGS. 2 and 4.

Similarly to as described above with reference to FIG. 3, the method of FIG. 10 may further comprise training the MP model and the ML model using the feedback signal y(n) and the first signal x(n) input into the combination model by performing periodic and alternate updates to the MP model and the ML model.

In some examples, the method of FIG. 10 comprises triggering the start of the first time period in response to a request to update the ML model. In some examples, the method of FIG. 10 comprises triggering the start of the second time period in response to a request to update the MP model.

### Direct Learning Architecture and Indirect Learning Architecture

It will be appreciated that the combination model may be trained using DLAs or ILAs.

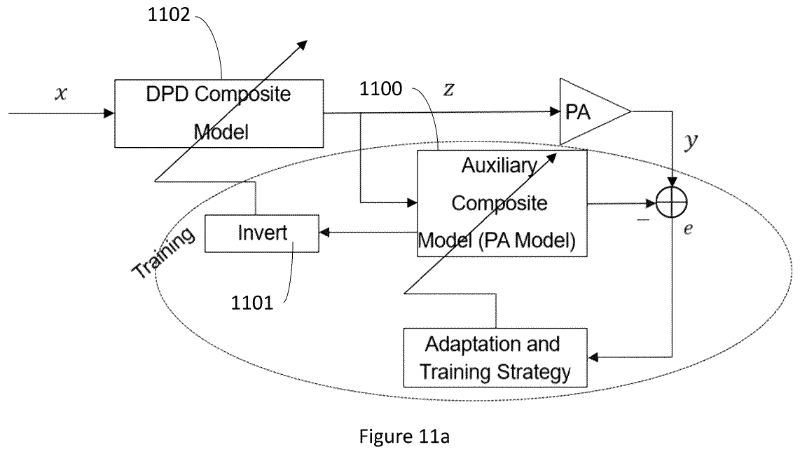

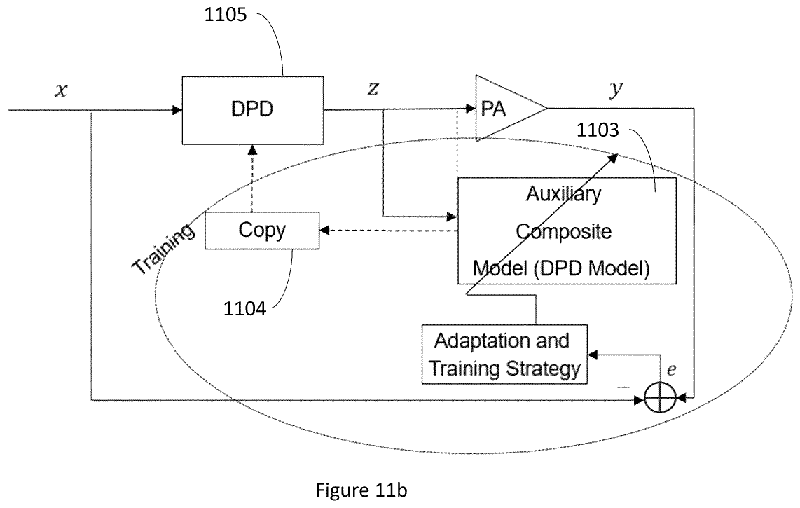

FIG. 11a illustrates an example of an indirect learning architecture in which the combination model is trained outside of the signal path. In this example, a model 1100 of the PA is effectively learnt. The parameters of this model 1100 are then inverted in 1101 to provide the combination model 1102 in the signal path.

FIG. 11b illustrates an example of a direct learning architecture in which the combination model is trained outside of the signal path. In this example, the model 1103 is trained and the parameters of the model 1103 are then copied in 1104 to provide the combination model 1105 in the signal path.

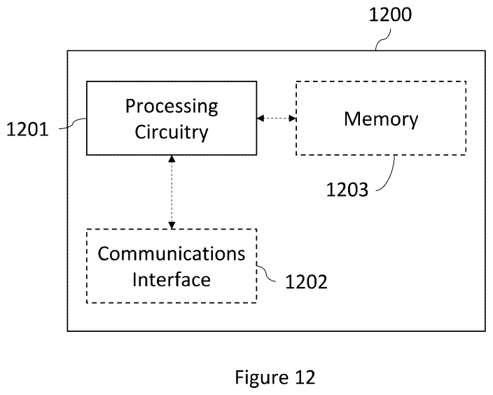

FIG. 12 illustrates an DPD module 1200 comprising processing circuitry (or logic) 1201. The processing circuitry 1201 controls the operation of the DPD module 1200 and can implement the method described herein in relation to an DPD module 1200. The processing circuitry 1201 can comprise one or more processors, processing units, multi-core processors or modules that are configured or programmed to control the DPD module 1200 in the manner described herein. In particular implementations, the processing circuitry 1201 can comprise a plurality of software and/or hardware modules that are each configured to perform, or are for performing, individual or multiple steps of the method described herein in relation to the DPD module 1200.

Briefly, the processing circuitry 1201 of the DPD module 1200 is configured to: receive a first signal, x(n); and input the first signal x(n) into a combination model, wherein the combination model comprises a machine learning, ML, model and a memory polynomial, MP, model; and output the transmit signal z(n) from the combination model.

In some embodiments, the DPD module 1200 may optionally comprise a communications interface 1202. The communications interface 1202 of the DPD module 1200 can be for use in communicating with other nodes, such as other virtual nodes. For example, the communications interface 1202 of the DPD module 1200 can be configured to transmit to and/or receive from other nodes requests, resources, information, data, signals, or similar. The processing circuitry 1201 of DPD module 1200 may be configured to control the communications interface 1202 of the DPD module 1200 to transmit to and/or receive from other nodes requests, resources, information, data, signals, or similar.

Optionally, the DPD module 1200 may comprise a memory 1203. In some embodiments, the memory 1203 of the DPD module 1200 can be configured to store program code that can be executed by the processing circuitry 1201 of the DPD module 1200 to perform the method described herein in relation to the DPD module 1200. Alternatively or in addition, the memory 1203 of the DPD module 1200, can be configured to store any requests, resources, information, data, signals, or similar that are described herein. The processing circuitry 1201 of the DPD module 1200 may be configured to control the memory 1203 of the DPD module 1200 to store any requests, resources, information, data, signals, or similar that are described herein.

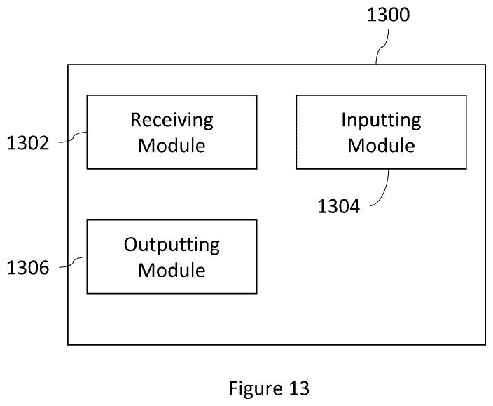

FIG. 13 is a block diagram illustrating an DPD module 1300 according to some embodiments. The DPD module 1300 can perform DPD to provide a transmit signal. The DPD module 1300 comprises a receiving module 1302 configured to receive a first signal x(n). The DPD module 1300 comprises an inputting module 1304 configured to input the first signal x(n) into a combination model, wherein the combination model comprises an ML model and an MP model. The DPD module 1300 further comprises an outputting module 1306 configured to output the transmit signal z(n). The DPD module 1300 may operate in the manner described herein in respect of an DPD module.

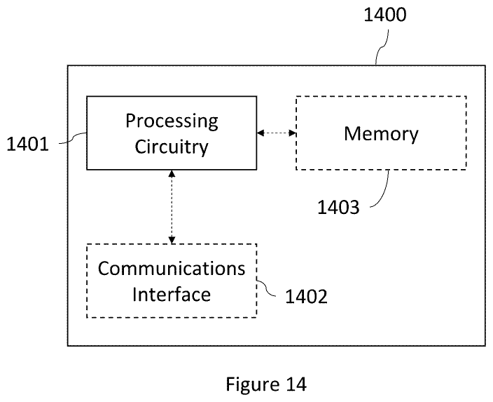

FIG. 14 illustrates an DPD module 1400 comprising processing circuitry (or logic) 1401. The processing circuitry 1401 controls the operation of the DPD module 1400 and can implement the method described herein in relation to an DPD module 1400. The processing circuitry 1401 can comprise one or more processors, processing units, multi-core processors or modules that are configured or programmed to control the DPD module 1400 in the manner described herein. In particular implementations, the processing circuitry 1401 can comprise a plurality of software and/or hardware modules that are each configured to perform, or are for performing, individual or multiple steps of the method described herein in relation to the DPD module 1400.

Briefly, the processing circuitry 1401 of the DPD module 1400 is configured to: train the ML model during a first time period; disable training of the MP model during the first time period; train the MP model during a second time period; and disable training of the ML model during the second time period.

In some embodiments, the DPD module 1400 may optionally comprise a communications interface 1402. The communications interface 1402 of the DPD module 1400 can be for use in communicating with other nodes, such as other virtual nodes. For example, the communications interface 1402 of the DPD module 1400 can be configured to transmit to and/or receive from other nodes requests, resources, information, data, signals, or similar. The processing circuitry 1401 of DPD module 1400 may be configured to control the communications interface 1402 of the DPD module 1400 to transmit to and/or receive from other nodes requests, resources, information, data, signals, or similar.

Optionally, the DPD module 1400 may comprise a memory 1403. In some embodiments, the memory 1403 of the DPD module 1400 can be configured to store program code that can be executed by the processing circuitry 1401 of the DPD module 1400 to perform the method described herein in relation to the DPD module 1400. Alternatively or in addition, the memory 1403 of the DPD module 1400, can be configured to store any requests, resources, information, data, signals, or similar that are described herein. The processing circuitry 1401 of the DPD module 1400 may be configured to control the memory 1403 of the DPD module 1400 to store any requests, resources, information, data, signals, or similar that are described herein.

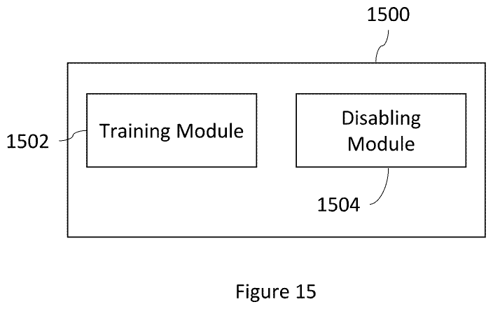

FIG. 15 is a block diagram illustrating an DPD module 1500 according to some embodiments. The DPD module 1500 can perform training of a combination model to perform DPD. The DPD module 1500 comprises a training module 1502 configured to train the ML model during a first time period and train the MP model during a second time period. The DPD module 1500 further comprises a disabling module 1504 configured to disable training of the MP model during the first time period and disable training of the ML model during the second time period. The DPD module 1500 may operate in the manner described herein in respect of an DPD module.

There is also provided a computer program comprising instructions which, when executed by processing circuitry (such as the processing circuitry 1201 of the DPD module 1200 described earlier), cause the processing circuitry to perform at least part of the method described herein. There is provided a computer program product, embodied on a non-transitory machine-readable medium, comprising instructions which are executable by processing circuitry to cause the processing circuitry to perform at least part of the method described herein. There is provided a computer program product comprising a carrier containing instructions for causing processing circuitry to perform at least part of the method described herein. In some embodiments, the carrier can be any one of an electronic signal, an optical signal, an electromagnetic signal, an electrical signal, a radio signal, a microwave signal, or a computer-readable storage medium.

### Simulation Results for GB Tree Assisted MP Based DPD

Embodiments described herein obtain robust DPD performance, particularly in conjunction with HAD beamforming M-MIMO structures under both static and dynamic traffic that would significantly reduce performance of traditional DPD methods.

Although MP models typically provide good performance in single antenna and/or small number of antenna structures considering one RX/TX chain, the performance of MP models significantly decreases when used in systems comprising a large number of antennas/M-MIMO structures in a single path with or without dynamic traffic.

The performance of DPD when utilizing traditional polynomial based algorithms such as MP as the natural reference with a HAD beamforming M-MIMO structure is significantly degraded in terms of NMSE and ACEPR based on the results as seen in reference [4].

When only ML based DPD is considered as the base-line algorithm herein, the proposed ML assisted MP based DPD gives approximately 6 dB and 4 dB better performance in terms of NMSE under static and dynamic traffic, respectively.

Due to the good performance of our proposed algorithm under HAD beamforming M-MIMO structure, it may be considered unnecessary to implement digital beamforming M-MIMO for each TX chain with huge computational and hardware complexities.

The following sets out experimental results of a study into the performance of i) without DPD, ii) only ML based DPD, and iii) our proposed ML assisted MP based DPD.

Normalized individual power amplifier output spectra of 16 different power amplifier models are applied at a 120 MHz sample rate. The transmitted orthogonal frequency-division multiplexing (OFDM) carrier is 20 MHz bandwidth and the peak-to-average power ratio (PAPR) is 7.7 dB. To evaluate the performance of the different behavioral modelling techniques, NMSE and ACEPR are used. The NMSE evaluates the performance of different DPD compensation techniques, and may be defined as

$${NMSE}_{dB} = 10 {log}_{10} \frac{{\sum }_{n = 1}^{N} {\vert {e}_{model} [ n ] \vert}^{2}}{{\sum }_{n = 1}^{N} {\vert {y}_{meas} [ n ] \vert}^{2}}$$

where e_{model}[n]=yₘₑₐₛ[n]−y_{model}[n] is the error signal between a measured signal and a predicted signal. On the other hand, ACEPR evaluates only the out-of-band modeling performance, computing a ratio between the error signal power over an adjacent channel and a desired channel power of the measured signal

$$( {P}_{error}^{adj} and {P}_{meas}^{ch} ) , as$$

$${ACEPR}_{dB} = 10 {log}_{10} \frac{{P}_{error}^{adj}}{{P}_{meas}^{ch}} .$$

The training networks of ML (specifically GB) based methods are applied once and saved for the future test signals. In the data processing stage, the different training and test datasets are considered with the total number of samples N=100 000.

It is noted that when dynamic traffic is considered as an example of 10 different power levels, each data portion includes 10 000 number of samples. The main reason for this process is to capture two uncorrelated datasets as if there is a strong correlation between training and test data, the performance of the DPD will be inaccurate.

In the proposed ML (specifically GB) assisted MP based DPD on HAD beamforming M-MIMO algorithms, the maximum depth of 100 and 1000 number of estimators are chosen with 0.01 learning rate considering memory order M=4 in the GB regression part. For the MP part, a polynomial order of P=7 is used (with odd orders only considered) and a memory order of M=4. For the base-line algorithm to have fair comparison, the same parameters are considered for only the ML based DPD method. Once the training stage is completed, the different test signals are applied in the prediction stage using the saved fitting network. Finally, the NMSE and ACEPR are calculated after forming the complex signals from the real-valued predictor outputs.

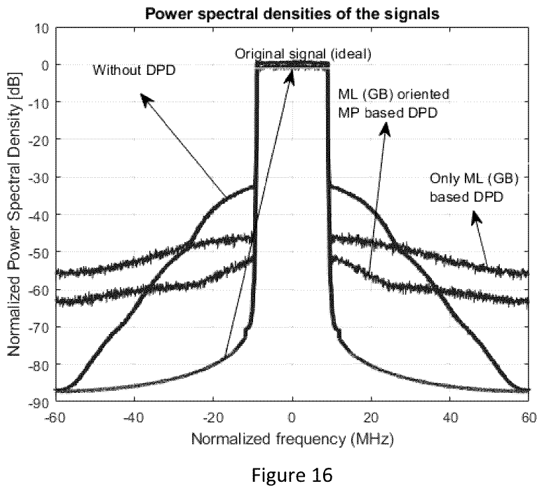

FIG. 16 illustrates normalised power spectral density as a function of frequency for signals without DPD, with ML assisted MP based DPD, and with only ML based DPD under static traffic conditions.

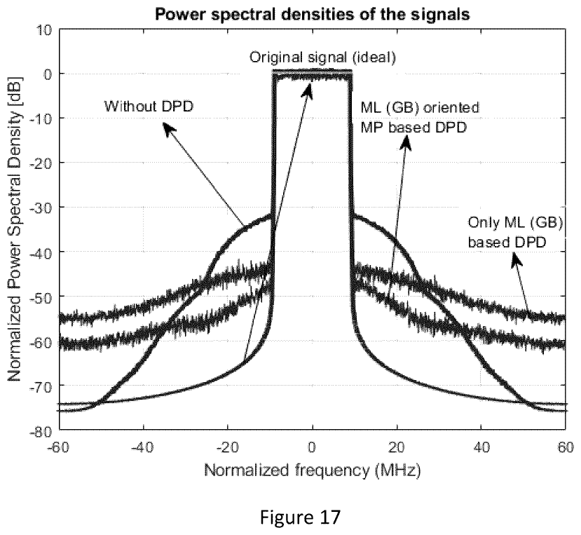

FIG. 17 illustrates normalised power spectral density as a function of frequency for signals without DPD, with ML assisted MP based DPD, and with only ML based DPD under dynamic traffic conditions.

As seen in both FIG. 16 (under static traffic as a more idealistic environment) and FIG. 17 (under dynamic traffic as a more realistic environment), there is significant performance degradation on nonlinearity compensations considering only GB based DPD out-of-band (adjacent channel) parts. On the contrary, the proposed GB assisted MP based DPD approach under HAD beamforming M-MIMO significantly gives performance improvement. As natural, dynamic traffic decreases the performance of all algorithms compared to the static traffic. However, the proposed approach still gives reasonably good performance under dynamic traffic as well. The numerical values for both NMSE and ACEPR are given in details in the following Table I and Table II.

TABLE I
NMSE AND ACEPR OF ML AND POLYNOMIAL BASED
ALGORITHMS FOR THE BASE STATION POWER
AMPLIFIER USING THE STATIC TRAFFIC.

| Machine Learning and Polynomial based | | |
|---|---|---|
| Algorithms | NMSE | ACEPR |
| Without DPD | −29.5342 | −37.7095 |
| With ML (GB) based DPD | −40.1015 | −46.6949 |
| With ML (GB) aided MP based DPD | −46.0607 | −54.8728 |

TABLE II
NMSE AND ACEPR OF ML AND POLYNOMIAL BASED
ALGORITHMS FOR THE BASE STATION POWER
AMPLIFIER USING THE DYNAMIC TRAFFIC.

| Machine Learning and Polynomial based | | |
|---|---|---|
| Algorithms | NMSE | ACEPR |
| Without DPD | −28.6704 | −37.0850 |
| With ML (GB) based DPD | −37.8501 | −44.7948 |
| With ML (GB) aided MP based DPD | −41.6598 | −50.4569 |

Herein, two cases as “a single power level near to the saturation level of PA” and “a single predictor at 10 different output power levels of PA” are considered to evaluate the performance of the learning techniques under HAD beamforming M-MIMO structure as seen in Table I and Table II, respectively. Consideration of a HAD beamforming M-MIMO structure together with the single predictor decreases the computational complexity significantly compared to fully digital beamforming M-MIMO structure which includes DPD for each antenna.

It is noted that one NMSE and one ACEPR values are shown in Table I and Table II for the proposed and base-line (reference) method that the single predictor is applied to obtain the performance under either static or combination/merging of ten different power levels considering HAD beamforming M-MIMO. Based on the results in Table I and Table II, GB assisted MP based DPD approach gives significantly better performance than the reference only GB based approach under both static and dynamic traffic.

It can be seen from Table I and Table II that, while the NMSE performances of the only GB based DPD under static and dynamic are −40.10 dB and −37.85 dB, respectively, NMSE performances of proposed GB assisted MP based DPD under static traffic and dynamic traffic are −46.06 dB and −41.66 dB, respectively. Similarly, while the ACEPR performances of the only GB based DPD under static and dynamic traffic are −46.69 dB and −44.79 dB, respectively, ACEPR performances of proposed GB assisted MP based DPD under static traffic and dynamic traffic are −54.87 dB and −50.45 dB, respectively.

As a conclusion, the proposed ML specifically GB assisted MP based DPD gives approximately 5 dB (average) performance improvement compared to only GB based DPD in terms of NMSE. Similarly, there are approximately 6 dB (average) performance improvements in terms of ACEPR considering the proposed approach compared to only GB based DPD as seen in the same tables.

### Simulation Results for Neural Network Assisted MP Based PA Modelling.

In these results the signal used is generated according to the NR base station (BS) radio transmission standards. Two multiband/wideband signals with 50 MHz bandwidth on 600 MH2 instantaneous bandwidth (IBW) are considered to see the nonlinearity effects in the experiments. The center frequency of carriers is 3.6864 GHz. The output power of the PA is 39 dBm. The sampling rate of data acquisition is 1.47456 GHz.

Capturing/getting the data is not problematic for these simulations, as the same mentality can be used as in the baseline algorithms such as transmitter observation receiver (TOR). Additionally, if offline training is considered, the data can be captured in different time periods and proceed with training. Then, the saved network may be used with the test data to obtain the predicted signal.

To evaluate the performance of the different behavioral modelling techniques, NMSE is used which evaluates the full-band modelling accuracy of the PA and DPD behavioral model, and can be defined as

$${NMSE}_{dB} = 10 {log}_{10} \frac{{\sum }_{n = 1}^{N} {\vert {y}_{meas} [ n ] - {y}_{model} [ n ] \vert}^{2}}{{\sum }_{n = 1}^{N} {\vert {y}_{meas} [ n ] \vert}^{2}} .$$

where yₘₑₐₛ[n] and y_{model}[n] are the measured signal and predicted signals, respectively.

In the data processing stage, the different training and test datasets are considered with the number of samples N=65536. The main reason of this process is to capture uncorrelated two pieces of dataset due so that there is a strong correlation between training and test data, otherwise the performance of the PA modelling will be inaccurate.

In the NN algorithm (either in only NN or in NN assisted MP based approach), 4 layers and 50 neurons in each layer have been applied with some optimization tests to find the best optimal results. For the reference only MP model and the NN assisted MP based approach, polynomial order P=9 is used (with odd orders only considered) and memory order M=4. Similarly, M=4 is used in NN algorithms to have a fair comparison. Once the training stage is completed in ML approach, the different test signals are applied in the prediction stage using the saved fitting network. Finally, the NMSE is calculated after forming the complex signals from the real-valued predictor outputs.

The NMSE performances of the proposed cascade & parallel NN assisted MP based and reference only NN and only MP based algorithms using random and optimal delays in MP are given in detail in the following Table I and Table II, respectively. Together with these results, the parametrization used in each model is also presented, in order to give the reader a better understanding regarding the dimensioning of each approach.

TABLE I
NMSE OF PROPOSED CASCADE & PARALLEL NN ASSISTED
MP BASED AND REFERENCE ONLY NN AND ONLY
MP ALGORITHMS FOR THE BS PA USING
RANDOM ADDRESS AND DATA DELAYS IN MP.

| | Cascade | Parallel | | |
|---|---|---|---|---|
| PA modeling | MP + NN | MP/NN | Only NN | Only MP |
| Parametrization | 50, 50, 50, 50 | 50, 50, 50, 50 | 50, 50, 50, 50 | P = {1, 3, |
| used | | | | 5, 7, 9} |
| NMSE | −39.94 dB | −40.12 dB | −37.80 dB | −30.00 dB |

TABLE II
NMSE OF PROPOSED CASCADE & PARALLEL NN ASSISTED
MP BASED AND REFERENCE ONLY NN AND ONLY
MP BASED ALGORITHMS FOR THE BS PA
USING OPTIMAL ADDRESS AND DATA DELAYS IN MP.

| | Cascade | Parallel | | |
|---|---|---|---|---|
| PA modeling | MP + NN | MP/NN | Only NN | Only MP |
| Parametrization | 50, 50, 50, 50 | 50, 50, 50, 50 | 50, 50, 50, 50 | P = {1, 3, |
| used | | | | 5, 7, 9} |
| NMSE | −40.48 dB | −40.43 dB | −37.80 dB | −37.75 dB |

As seen in Table I, while NMSE performances of the proposed cascade & parallel NN assisted MP based approaches under random delays in MP under wideband & multiband scenarios are −39.94 dB and −40.12 dB, respectively, NMSE performance of the only MP based approach as reference under random address and data delays is −30.00 dB.

As seen in Table II, while NMSE performances of the proposed cascade & parallel NN assisted MP based approaches under random address and data delays in MP under wideband & multiband scenarios are −40.48 dB and −40.43 dB, respectively, NMSE performance of the only MP based approach as reference under random address and data delays is −37.75 dB.

As a conclusion, due to effects of tap optimization (finding the optimal address and data delays) in MP algorithms, there is approximately 10 dB performance degradation in the MP based approaches compared to the proposed cascade & parallel NN assisted MP based approaches. Additionally, the proposed NN assisted MP based approaches are not sensitive to the tap optimization in MP process even though NN is working together with MP. The performance degradation can be ignorable. However, only MP based approaches are quite sensitive to tap optimization that the performance degradation is approximately 8 dB.

As it is mentioned, the behavior/performance of the proposed solutions is analysed and demonstrated by simulations, which specifically target PA modelling, instead of DPD. This is the reason why other metrics, such as error vector magnitude (EVM) or adjacent channel leakage ratio (ACLR), are not provided.

However, it is noted that the DPD systems essentially perform a modelling problem, since it needs to estimate the characteristics of the PA, including nonlinear and memory effects. This is the reason why we believe that PA modelling result can give a precise estimate about the performance and behavior of the whole algorithm, when utilized as a DPD. At the end, the essence of the proposed solutions is to model the PA behavior, a process that is the key to a good performance in pre-distortion operation.

It Is noted that offline training may be used, like most of NN applications. But online training may also be used, because it can compensate the distortion with real data to find the time varying nonlinear properties of PA due to the dynamic traffic, dynamic operation, or dynamic environment. A plausible proposal would be to use the offline training in a static environment, but in the dynamic environment, online can be applied for a while to compensate the dynamic behavior.

Finally, the only MP model requires a huge effort in both terms of computational complexity and tap optimization. This is particular caused by the need to find optimal delays for each carrier configuration on each PA, which is done offline. This procedure requires a tremendous amount of time, and hence, both design cost and time-to-market are increased. However, as reviewed herein, the proposed cascade NN+MP and parallel NN/MP approaches do not suffer from this problematic and have a lower design cost and time effort. This makes the proposed approaches very attractive and proves that future communication systems will greatly benefit from them.

The proposed ML assisted MP based DPD on HAD M-MIMO beamforming has below advantages:

Improved performance under both static and dynamic traffic and under this structure where almost no performance degradation is observed on the performances of both NMSE and ACEPR.

Noteworthy, the performance of the base-line algorithms such as only GB based DPD gives 6 dB and 4 dB worse performance in terms of NMSE compared to the embodiments described herein (under static and dynamic traffic, respectively).

Additionally, the embodiments described herein give 8 dB and 6 dB better performance in terms of ACEPR compared to base-line only GB based approach under static and dynamic traffic, respectively.

This high performance may boost the application of HAD beamforming M-MIMO structure with less computational and hardware complexity. On the contrary, to keep the same performances in the base-line algorithms such as only MP and only GB, it may be required to have extra processes that includes huge computational complexity and the memory resources on HAD beamforming M-MIMO.

Additionally, while traditional DPD approaches in fully digital beamforming structure include higher degree of freedom resulting with the good performance, the implementation of DPD on digital beamforming M-MIMO structure requires huge computational and hardware complexities compared to DPD on HAD beamforming M-MIMO structure.

Ideal input signals and the output of GD based adaptation are complex and the complex data can directly be applied in MP based approach. However, the ML (e.g. GB) algorithms naturally work only with real-valued signals compared to the MP based approaches. Hence, it is firstly required to convert the complex-valued signals to the real signals in a matrix format considering also memory stages in ML based approaches.

Additionally, ML assisted MP based PA and DPD modeling requires low power consumption and high energy efficiency due to its simplicity on tap optimization. Because, instead of full model, each input data sample is processed with the related nonlinear operators. Additionally, the proposed approach thanks to ML increases the degrees of freedom in the modeling and at the same time, creates more diversity in the basis functions. Hence, the proposed ML assisted MP based method achieves very high modeling accuracy with less required memory (hardware) resource and low power consumption on wideband and multiband scenarios.

Embodiments described herein allow for easy deployment. For example, two approaches may be applied to radio products with affordable effort. First, offline training and online prediction may be applied. The training may be performed in the production line with pre-defined training data. Then the resultant trees may be stored in a database. Since the prediction usually does not need high computation, this approach may minimize the cost of the application. Second, online training and online prediction may be performed. The training may then be performed periodically based on the data provided by the observation path. In this case, the training may follow the state of power amplifier and may extract state-of-the-art behavior. To reduce the computation, it may be possible to lengthen the periodicity, or decrease the scale of trees.

Embodiments described herein also improve energy efficiency and lessen power consumption. For example, the as illustrated in the simulation results above, the GB assisted MP based DPD on HAD beamforming M-MIMO improves the energy efficiency in the structure. Furthermore, with the possibility of the offline training implementation this means that efficiency can be further improved as the repeating of the training may not be required if the environment does not often change.

### The Proposed ML Assisted MP Based Approach Also Has the Below Advantages:

### Empowering Efficient Modeling for Nonlinear Devices on Wideband and Multiband Scenarios:

Wideband and multiband scenarios, which are popular in today's realistic transmission according to the requirements of the customers, are very challenging for existing approaches. However, embodiments described herein may handle these scenarios in an efficient way.

### Outstanding Performance for Wideband and Multiband Use Cases:

The proposed ML assisted MP based approaches (without optimal address and data delays in MP stage) give outstanding performance on wideband and multiband scenarios where almost no performance degradation is observed on the performance of NMSE compared to the same approach with optimal address and data delays in MP stage.
Noteworthy, traditional MP algorithms without optimal address and data delays in the filters give approximately 8 dB worse performance in terms of NMSE compared to the MP algorithms with optimal address and data delays in the filters.
However, the proposed ML assisted MP based approaches give approximately 10 dB (average) and 3 dB (average) better performance in terms of NMSE compared to MP based approaches with random address and data delays and with optimal address and data delays on wideband and multiband scenarios, respectively.

### No Need for Significant Complexity Increments and Effort on Finding the Optimal Data and Address Delays:

Finding the optimal address and data delays in the filters of MP requires huge effort that the optimal delays for each carrier configuration on each PA must be offline searched.
However, the proposed ML assisted MP based approach does not require tap optimization for MP stage and performance degradation can be ignorable.
Searching of the optimal data and address delays normally requires tremendous time and hence, both design cost and time-to-market are increased. However, the proposed approach, which does not require the tap optimization for MP stage and due to that it just needs little design cost, time and effort.

### Easy-to-Deploy Models:

Two approaches can be applied to radio products with affordable effort. First, offline training and online prediction. The training is performed in the production line with pre-defined training data. Then the resultant network and polynomials are stored in database. Since the prediction usually does not need high computation, this approach can minimize the cost of application.
Second, online training and online prediction. The training is performed periodically based on the data provided by the observation path. In this case, the training can follow the state of PA and extract state-of-the-art behavior. To reduce the computation, it is possible to enlarge the periodicity, or decrease the scale of model.

### Improved Energy Efficiency:

The proposed approach, which achieves very high modeling accuracy with less required memory (hardware) resource and low power consumption, increases the degrees of freedom in the modeling and at the same time, creates more diversity in the basis functions.
ML assisted MP based approach improves the energy efficiency in PA and DPD modeling with the possibility of the offline training implementation in long time period that the repeating of the training does not require short time period if the building practice (environment) does not often change.

### REFERENCE LIST

1. E. G. Larsson, O. Edfors, F. Tufvesson, and T. L. Marzetta, “Massive MIMO for next generation wireless systems,” IEEE Commun. Mag., vol. 52, no. 2, pp. 186-195, February 2014.
2. F. Boccardi, R. W. Heath, A. Lozano, T. L. Marzetta, and P. Popovski, “Five disruptive technology directions for 5G,” IEEE Commun. Mag., vol. 52, no. 2, pp. 74-80, February 2014.
3. A. F. Molisch et al., “Hybrid beamforming for massive MIMO: A survey,” IEEE Commun. Mag., vol. 55, no. 9, pp. 134-141, September 2017.
4. M. Abdelaziz, L. Anttila, A. Brihuega, F. Tufvesson and M. Valkama, “Digital predistortion for hybrid MIMO transmitters,” in IEEE Journal of Selected Topics in Signal Processing, vol. 12, no. 3, pp. 445-454, June 2018, doi: 10.1109/JSTSP.2018.2824981.
5. E. Bjornson, J. Hoydis, M. Kountouris, and M. Debbah, “Massive MIMO systems with non-ideal hardware: Energy efficiency, estimation, and capacity limits,” IEEE Trans. Inf. Theory, vol. 60, no. 11, pp. 7112-7139 November 2014.
6. D. R. Morgan et al., “A generalized memory polynomial model for digital predistortion of RF power amplifiers,” IEEE Trans. Signal Process., vol. 54, no. 10, pp. 3852-3860, 2006.
7. Sheppard, “Tree-based machine learning algorithms: Decision trees, random forests, and boosting” CreateSpace Ind. Publish. Platform, 2017.
8. J. Song, J. Zhao, F. Dong, J. Zhao, Z. Qian, and Q. Zhang, “A novel regression modeling method for PMSLM structural design optimization using a distance-weighted KNN algorithm,” IEEE Transactions on Industry Applications, vol. 54, no. 5, pp. 4198-426 September 2018.
9. M. A. Nielsen, “Neural networks and deep learning” Determination Press, 2018.
10. S. Dikmese, L. Anttila, P. Pascual Campo, M. Valkama and M. Renfors, “Behavioral modeling of power amplifiers with modern machine learning techniques,” IEEE MTT-S International Microwave Conference on Hardware and Systems for 5G and Beyond, Atlanta, GA, USA, August 2019.
11. C. Mollen, U. Gustavsson, T. Eriksson, and E. G. Larsson, “Out-of-band radiation measure for MIMO arrays with beamformed transmission,” in Proc. IEEE Int. Conf. Commun., May 2016, pp. 1-6.
12. J. Shen, S. Suyama, T. Obara, and Y. Okumura, “Requirements of power amplifier on super high bit rate massive MIMO OFDM transmission using higher frequency bands,” in Proc. IEEE Globecom Workshops, December 2014, pp. 433-437.
13. Y. Zou et al., “Impact of power amplifier nonlinearities in multi-user massive MIMO downlink,” in Proc. IEEE Globecom Workshops, December 2015, pp. 1-7.
14. C. Mollen, E. G. Larsson, U. Gustavsson, T. Eriksson and R. W. Heath, “Out-of-band radiation from large antenna arrays,” in IEEE Communications Magazine, vol. 56, no. 4, pp. 196-203, April 2018, doi: 10.1109/MCOM.2018.1601063.
15. Y. Guo, C. Yu and A. Zhu, “Power adaptive digital predistortion for wideband RF power amplifiers with dynamic power transmission,” IEEE Trans. Microw. Theory Techn., vol. 63. No. 11, pp. 1-13. 2015.
16. H. Gao and S. Dikmese, “Linearization of a non-linear electronic device”, PCT/SE2020/050576.
17. A. Feng, S. Dikmese, and H. Gao, “Dimensionality reduction for DPD models”, PCT/CN2021/140366.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1.-49. (canceled)

50. A method of performing digital predistortion, DPD, to provide a transmit signal, z(n) wherein the transmit signal, z(n), is for deriving one or more amplifier signals, zₘ(n), for driving one or more power amplifiers, wherein the one or more power amplifiers are associated with a respective one or more antenna elements, the method comprising:
receiving a first signal, x(n);
inputting the first signal, x(n), into a combination model, wherein the combination model comprises a machine learning, ML, model and a memory polynomial, MP, model in a cascading structure or a parallel structure and the MP model is configured to receive an output of the ML model;
outputting the transmit signal z(n), from the combination model;
receiving a feedback signal, y(n), based on an output of the one or more power amplifiers;
training the ML model and training the MP model at the same time using the feedback signal and determining a cost function from the first signal and the feedback signal when training both the ML model and the MP model.

51. The method as claimed in claim 50 wherein training the MP model comprises:
performing gradient descent on the MP model utilizing a partial derivative of the cost function with respect to a coefficient of the MP model.

52. The method as claimed in claim 51 wherein training the ML mode comprises determining a feedback gradient as a derivative of the cost function with respect to the output of the ML model.

53. The method as claimed in claim 52 wherein training the ML model comprises performing gradient descent utilizing one or more partial derivatives of the cost function with respect to one or more respective parameters of the ML model.

54. The method as claimed in claim 50 wherein the MP model and the ML model both receive the first signal, x(n); and wherein the transmit signal, z(n) is derived from a first intermediate signal output from the MP model and a second intermediate signal output from the ML model.

55. The method as claimed in claim 54 wherein the transmit signal comprises a sum of the first intermediate signal and the second intermediate signal.

56. The method of claim 55 wherein training the MP model comprises:
performing gradient descent on the MP model utilizing a partial derivative of the cost function with respect to the first intermediate signal.

57. The method of claim 56 wherein training the ML model comprises
performing gradient descent on the ML model utilizing a partial derivative of the cost function with respect to the second intermediate signal.

58. The method as claimed in claim 50 comprising training the combination model using an indirect learning architecture.

59. The method as claimed in claim 50 comprising training the combination model using a direct learning architecture.

60. The method as claimed in claim 50 wherein the transmit signal, z(n), is for deriving a plurality of amplifier signals zₘ(n).

61. The method as claimed in claim 60 comprising:
deriving the plurality of amplifier signals zₘ(n) by inputting the transmit signal, z(n), into an analog beamforming module.

62. The method as claimed in claim 50 wherein the transmit signal z(n), is for deriving one amplifier signal zₘ(n) and zₘ(n)=z(n).

63. A method of training a combination model for performing digital predistortion on a first signal x(n) input into the combination model to provide a transmit signal, z(n), wherein the transmit signal, z(n), is for deriving one or more amplifier signals, zₘ(n), for driving one or more power amplifiers, wherein the one or more power amplifiers are associated with a respective one or more antenna elements, wherein the combination model comprises a machine learning, ML, model and a memory polynomial, MP, model in a cascading structure or a parallel structure, the method comprising:
receiving a feedback signal, y(n), based on an output of the one or more power amplifiers;
training ML model during a first time period using the feedback signal, y(n) and the first signal x(n);
disabling training of the MP model during the first time period;
training the MP model during a second time period using the feedback signal, y(n) and the first signal x(n);
disabling training of the ML model during the second time period;
training the MP model and the ML model using the feedback signal y(n) and the first signal x(n) by performing periodic and alternate updates to the MP model and the ML model.

64. A DPD module for performing digital predistortion, DPD, to provide a transmit signal, z(n) wherein the transmit signal, z(n), is for deriving one or more amplifier signals, zₘ(n), for driving one or more power amplifiers wherein the one or more power amplifiers are associated with a respective one or more antenna elements, the DPD module comprising processing circuitry configured to:
receive a first signal, x(n); and
input the first signal x(n) into a combination model, wherein the combination model comprises a machine learning, ML, model and a memory polynomial, MP, model in a cascading structure or a parallel structure and the MP model is configured to receive an output of the ML model;
output the transmit signal z(n) from the combination model receive a feedback signal, y(n), based on an output of the one or more power amplifiers;
train the ML model and training the MP model at the same time using the feedback signal and determining a cost function from the first signal and the feedback signal when training both the ML model and the MP model.

65. The DPD module as claimed in claim 64 wherein the processing circuitry configured to train the MP model comprises processing circuitry configured to perform gradient descent on the MP model utilizing a partial derivative of the cost function with respect to a coefficient of the MP model.

66. A DPD module for training a combination model for performing digital predistortion on a first signal x(n) input into the combination model to provide a transmit signal, z(n) wherein the transmit signal, z(n), is for deriving one or more amplifier signals, zₘ(n), for driving one or more power amplifiers, wherein the one or more power amplifiers are associated with a respective one or more antenna elements, wherein the combination model comprises a machine learning, ML, model and a memory polynomial, MP, model in a cascading structure or a parallel structure, the DPD module comprising processing circuitry configured to:
receive a feedback signal, y(n), based on an output of the one or more power amplifiers;
train the ML model during a first time period using the feedback signal, y(n) and the first signal x(n);
disable training of the MP model during the first time period;
train the MP model during a second time period using the feedback signal, y(n) and the first signal x(n);
disable training of the ML model during the second time period; and
train the MP model and the ML model using the feedback signal y(n) and the first signal x(n) by performing periodic and alternate updates to the MP model and the ML model.

67. A beamforming module for performing digital predistortion, DPD, the beamforming module comprising a DPD module as claimed in claim 64.

68. The beamforming module as claimed in claim 67 wherein the beamforming module comprises a HAD MIMO beamforming module.

69. The beamforming module as claimed in claim 67 wherein the beamforming module comprises a digital beamforming module.
